(19) United States
(12) Patent Application Publication
(10) Pub. No.: US 2016/0324016 A1
(43) Pub. Date: Nov. 3, 2016

(54) GLASS ARTICLES HAVING FILMS WITH MODERATE ADHESION, RETAINED STRENGTH AND OPTICAL TRANSMITTANCE

(71) Applicant: CORNING INCORPORATED, CORNING, NY (US)

(72) Inventors: Robert Alan Bellman, Painted Post, NY (US); Jiangwei Feng, Newtown, PA (US); Shandon Dee Hart, Corning, NY (US); Jen-Chieh Lin, Zhubei City (TW); Prantik Mazumder, Ithaca, NY (US); Chandan Kumar Saha, Franklin, MI (US)

(21) Appl. No.: 15/141,140

(22) Filed: Apr. 28, 2016

Related U.S. Application Data
(60) Provisional application No. 62/155,051, filed on Apr. 30, 2015.

(51) Int. Cl. H05K 5/00; B32B 7/02; B32B 17/06; H05K 5/03; C23C 16/50

(52) U.S. Cl. CPC H05K 5/0017; H05K 5/03; C23C 16/50; B32B 17/06; B32B 7/02; B32B 2457/20

(57) ABSTRACT

One or more aspects relate to an article that includes a glass substrate having a first average strain-to-failure; and a crack mitigating layer disposed on a first major surface of the substrate forming a first interface. The article also includes a film disposed on the crack mitigating layer forming a second interface and having a second average strain-to-failure that is less than the first average strain-to-failure. Further, at least one of the first and second interfaces exhibits a moderate adhesion such that at least a portion of the crack mitigating layer experiences one or more of a cohesive failure and an adhesive failure at the interfaces when the article is strained to a strain level between the first average strain-to-failure and the second average strain-to-failure. In addition, the refractive index of the crack mitigating layer is between or the same as the refractive indices of the substrate and the film.

### CROSS-REFERENCE TO RELATED APPLICATIONS

This application claims the benefit of priority under 35 U.S.C. §119 of U.S. Provisional Application Ser. No. 62/155,051 filed on Apr. 30, 2015, the content of which is relied upon and incorporated herein by reference in its entirety.

### BACKGROUND

This disclosure relates to articles with a glass substrate that has a film disposed on its surface, and a modified interface between the film and the glass substrate such that the glass substrate substantially retains its average flexural strength, and the film retains key properties for its application, including optical properties associated with display device applications.

Articles including a glass substrate, which may be strengthened or strong as described herein, have found wide usage recently as a protective cover glass for displays, especially in touch-screen applications, and there is a potential for their use in many other applications, such as automotive or architectural windows, glass for photovoltaic systems and glass substrates for use in other electronic device applications. Further, such articles are often used in consumer electronic products to protect critical devices within the product, to provide a user interface for input and/or display, and/or many other functions. These consumer electronic products include mobile devices, such as smart phones, mp3 players and computer tablets.

Strong optical performance is required of many of these articles in terms of maximum light transmission and minimum reflectivity when the articles are used in cover substrate and in some housing substrate applications. In addition, cover substrate applications often require that the color exhibited or perceived, in reflection and/or transmission, does not change appreciably as the viewing angle (or incident illumination angle) is changed. This because, if the color, reflectivity or transmission changes with viewing angle to an appreciable degree, the user of the product incorporating the cover glass will perceive a change in the color or brightness of the display, which can diminish the perceived quality of the display. Of these changes, a change in color is often the most noticeable and objectionable to users.

In many of these applications it can be advantageous to apply a film to the glass substrates. Exemplary films include indium-tin-oxide (ITO) or other transparent conductive oxides (e.g., aluminum and gallium doped zinc oxides and fluorine doped tin oxide), hard films of various kinds (e.g., diamond-like carbon, Al₂O₃, AlN, AlOₓN_{y}, Si₃N₄, SiOₓN_{y}, SiAlₓO_{y}N_{z}, TiN, TiC), IR or UV reflecting layers, conducting or semiconducting layers, electronics layers, thin-film-transistor layers, or anti-reflection (AR) films (e.g., SiO₂, Nb₂O₅ and TiO₂ layered structures). In many instances these films must necessarily be hard and/or have a high elastic modulus, or otherwise their other functional properties (e.g., mechanical, durability, electrical conductivity, optical properties) will be degraded. In most cases these films are thin films, that is, they generally have a thickness in the range of 0.005 μm to 10 μm (e.g., 5 nm to 10,000 nm).

When a film is applied to a surface of a glass substrate, which may be strengthened or characterized as strong, the average flexural strength of the glass substrate may be reduced, for example, when evaluated using ball-drop or ring-on-ring strength testing. This behavior has been measured to be independent of temperature effects (i.e., the behavior is not caused by significant or measurable relaxation of surface compressive stress in the strengthened glass substrate due to any heating). The reduction in average flexural strength is also apparently independent of any glass surface damage or corrosion from processing, and is apparently an inherent mechanical attribute of the article, even when thin films having a thickness in the range from about 5 nm to about 10 μm are applied to the article. Without being bound by theory, this reduction in average flexural strength is believed to be associated with the adhesion between such films relative to the strengthened or strong glass substrates, the initially high average flexural strength (or high average strain-to-failure) of selected strengthened or strong glass substrates relative to selected films, together with crack bridging between such a film and the glass substrate.

When these articles employing glass substrates are employed in certain electronic device applications, for example, they may be subjected to additional high temperature processing during manufacturing. More specifically, the articles can be subjected to additional thermal treatments after deposition of the film on the glass substrates. These additional high temperature treatments often are the result of application-specific development of additional structures and components on the substrates and/or films of the article. Further, the deposition of the film itself on the substrate can be conducted at relatively high temperatures.

In view of these new understandings, there is a need to prevent films from reducing the average flexural strength of glass substrates in these articles. There is also a need to ensure that the average flexural strength of the glass substrates is substantially retained, even after high temperature exposures from film deposition processes and additional application-specific thermal treatments. In addition, a need also exists for retaining the optical properties of the substrate and film in view of the design, configuration and/or processing of the interface between the substrate and the film

### SUMMARY

A first aspect of this disclosure pertains to an article including a glass substrate having opposing major surfaces, a crack mitigating layer disposed on a first major surface, and a film disposed on the crack mitigating layer. In some embodiments, the crack mitigating layer is characterized by an elastic modulus of about 20 GPa or less. In one or more embodiments, the refractive index of the crack mitigating layer is greater than or equal to the refractive index of the substrate and less than or equal to the refractive index of the film.

One or more embodiments, the article includes a glass substrate having opposing major surfaces, a crack mitigating layer disposed on a first major surface forming a first interface, and a film disposed on the crack mitigating layer forming a second interface. In some embodiments, the article exhibits an effective adhesion energy at one or more of the first interface and the second interface of less than about 4 J/m². In some embodiments, the refractive index of the crack mitigating layer is greater than or equal to the refractive index of the substrate and less than or equal to the refractive index of the film.

In one or more embodiments, the article is characterized by an average flexural strength that is at least 90% of an average flexural strength of the substrate. In some embodiments, the article is characterized by an average flexural strength that is at least 90% of an average flexural strength of the substrate.

Optionally, the optical transmittance of the substrate and crack mitigating layer varies by 1% or less from the optical transmittance of the substrate.

The thickness of the crack mitigating layer may be about 300 nm or less or about 50 nm or less. In some instances, the crack mitigating layer has a thickness from about 50 nm to about 150 nm. The crack mitigating layer may include organosilicate material (e.g., a methylated silica material), though other materials are contemplated. In some embodiments. In some instances, the methylated silica is deposited with a chemical vapor deposition (CVD) process and derived from a trimethylsilane precursor. In one or more embodiments, the organosilicate material is deposited with a plasma-enhanced chemical vapor deposition (PECVD) process and derived from a hexyamethyldisiloxane (HMDSO) precursor.

The crack mitigating layer may include metal fluoride. Optionally, the crack mitigating layer may exhibit a porosity of about 20% or less. In some embodiments, the optical transmittance of the substrate and the crack mitigating layer varies by 1% or less from the optical transmittance of the substrate.

The film may include silicon nitride, silicon oxynitride, aluminum oxynitride, aluminum nitride, silicon aluminum oxynitride or indium tin oxide. In some embodiments, the film is an antireflective film, which can have a multilayer structure having alternating layers of a first material and a second material. The first material may include a high refractive index material (e.g., silicon nitride, silicon oxynitride, aluminum oxynitride, aluminum nitride, silicon aluminum oxynitride or indium tin oxide) and the second material may include a material having a lower refractive index than the high refractive index material (e.g., silicon oxide or silicon oxynitride).

A second aspect of this disclosure pertains to an electronic device comprising the articles described herein. In one or more embodiments, the device includes a housing having front, back, and side surfaces, electrical components that are at least partially inside the housing, a display at or adjacent to the front surface of the housing and the article disposed over the display.

### BRIEF DESCRIPTION OF THE DRAWINGS

FIG. 1 is an illustration of a laminate article comprising a glass substrate, a film and a crack mitigating layer, according to one or more embodiments.

FIG. 1A is an illustration of a laminate article comprising a glass substrate and a crack mitigating layer, according to one or more embodiments.

FIG. 2 is a schematic diagram of the development of a crack in a film or layer and its possible bridging modes.

FIG. 3 is an illustration of the theoretical model for the presence of a crack in a film or layer and its possible bridging as a function of elastic mismatch α.

FIG. 4 is a diagram illustrating the energy release ratio G_{d}/Gₚ.

FIG. 5A shows a top view of the glass substrate and an alternative embodiment of the crack mitigating layers shown in FIG. 1 (e.g., before disposing the film on the crack mitigating layer), and FIG. 1A.

FIG. 5B shows a cross-sectional view of the glass substrate and crack mitigating layer shown in FIG. 5A, taken along lines 1B-1B.

FIG. 5C shows a top view of the glass substrate and an alternative embodiment of the crack mitigating layer shown in FIGS. 1 and 1A (e.g., before disposing the film on the crack mitigating layer), and FIG. 1A.

FIG. 6A is a schematic diagram of adhesive failures associated with a crack mitigating layer interposed between a film and a substrate according to an aspect of this disclosure.

FIG. 6B is a schematic diagram of a cohesive failure in a crack mitigating layer interposed between a film and a substrate according to an aspect of this disclosure.

FIG. 6C is a schematic diagram of cohesive and adhesive failures associated with a crack mitigating layer on a substrate according to an aspect of this disclosure.

FIG. 7 is a graph presenting ring-on-ring load-to-failure performance of glass substrate controls and substrates having a silicon nitride film, a silicon nitride film and a barium fluoride crack mitigating layer, and a silicon nitride film and a barium fluoride/hafnium oxide crack mitigating layer according to an aspect of this disclosure given by Examples 1A-1D.

FIG. 8A is a graph presenting optical transmittance and reflectance data as a function of wavelength in the visible spectrum for glass substrate controls and substrates having a low density barium fluoride crack mitigating layer, an eight layer scratch resistant film (“8L SCR”), an 8L SCR film and a low density barium fluoride crack mitigating layer, and an 8L SCR film and a high density barium fluoride crack mitigating layer according to an aspect of this disclosure given by Examples 2A-2E.

FIG. 8B is a graph presenting absorption and haze (i.e., equal to 1−reflectance−transmittance) data for the samples depicted in FIG. 8A as a function of wavelength in the visible spectrum.

FIG. 9 is a graph presenting absorption and haze data as a function of final sample surface roughness for bare glass substrates, glass substrates having low- or high-density barium fluoride films, and glass substrates having low- or high-density barium fluoride films and glass substrates having low- or high-density barium fluoride films and a silicon nitride or an 8L SCR film given by Examples 3A1-A3, 3B1-B3, 3C1-C3 and 3D1-D3 according to an aspect of the disclosure.

FIG. 10 a graph presenting optical transmittance and reflectance data as a function of wavelength in the visible spectrum for glass substrate controls, substrates having a low- or high-density barium fluoride crack mitigating layer and a ten layer durable antireflective film (“10L DAR”), and substrates having a 10L DAR film according to an aspect of this disclosure given by Examples 4A-4D.

FIG. 11A is a graph presenting ring-on-ring load-to-failure performance of glass substrate controls and substrates having a silicon nitride film, a silicon nitride film and a low- or high-density 50 nm organosilicate crack mitigating layer, and a silicon nitride film and a low- or high-density 300 nm organosilicate crack mitigating layer according to an aspect of this disclosure given by Examples 1A, 1A1, 1B, and 5A-5D.

FIG. 11B is a graph presenting optical transmittance and reflectance data in the visible spectrum for the samples depicted in FIG. 11A given by Examples 1A, and 5A-5D.

FIG. 12 is a graph presenting optical transmittance and reflectance data in the visible spectrum for glass substrate controls, substrates having a 10L AR film, and substrates having a 50 nm or 300 nm thick organosilicate crack mitigating layer and a 10L AR film according to an aspect of this disclosure given by Examples 4A, 4B, 6A and 6B.

FIG. 13 is a graph presenting ring-on-ring load-to-failure performance of glass substrate controls and substrates having an indium-tin-oxide (ITO) film and silicate crack mitigating layer films of varying thicknesses according to an aspect of this disclosure given by Examples 7A-7F.

FIG. 14A is a graph plotting elastic modulus data as a function of indentation depth for an organosilicon crack mitigating layer prepared using an atmospheric pressure plasma-enhanced CVD process according to an aspect of the disclosure.

FIG. 14B is a graph plotting hardness data as a function of indentation depth given by test samples Exs. 8A-8G for the organosilicon crack mitigating layer of FIG. 14A.

FIG. 15 is a graph presenting optical transmittance data an organosilicon crack mitigating layer having a thickness of about 100 nm prepared using an atmospheric pressure plasma-enhanced CVD process according to a further aspect of this disclosure.

FIG. 16 is a scanning electron microscope (SEM) image from a cross section of a glass substrate with an organosilicon crack mitigating layer having a thickness of about 150 nm prepared using an atmospheric pressure plasma-enhanced CVD process according to a further aspect of this disclosure.

FIG. 17 is top plan view of a device according to one or more embodiments.

FIG. 18 is perspective view of the device shown in FIG. 17.

### DETAILED DESCRIPTION

In the following detailed description, numerous specific details may be set forth in order to provide a thorough understanding of embodiments of the disclosure. However, it will be clear to one skilled in the art when embodiments of the disclosure may be practiced without some or all of these specific details. In other instances, well-known features or processes may not be described in detail so as not to unnecessarily obscure the disclosure. In addition, like or identical reference numerals may be used to identify common or similar elements.

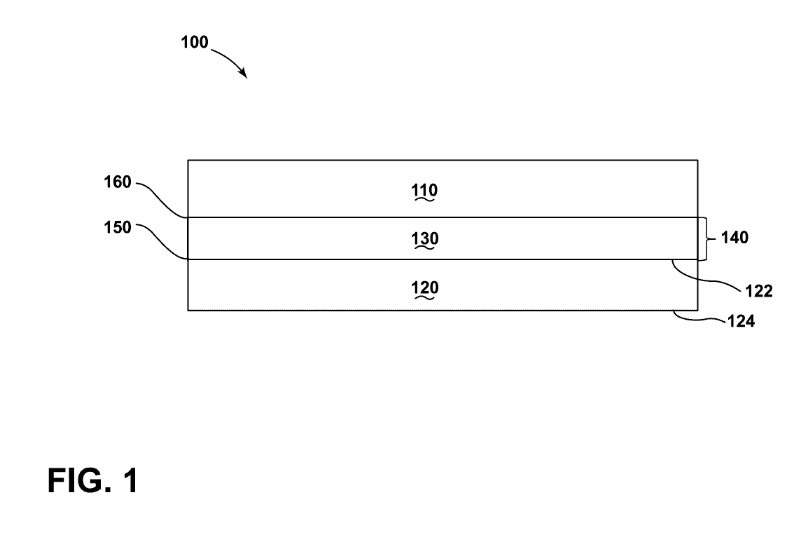

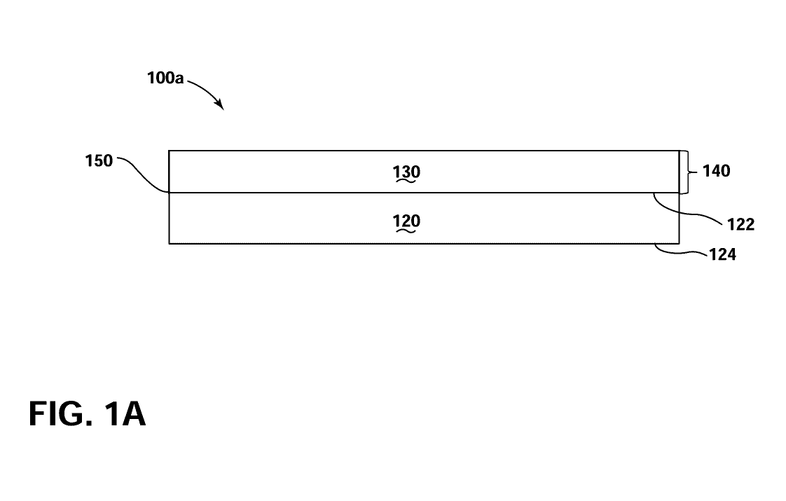

Referring to FIG. 1, aspects of this disclosure include a laminate article 100 including a film 110, a glass substrate 120 and a crack mitigating layer 130. Within the article, the interfacial properties at an effective interface 140 between the film 110 and the crack mitigating layer 130 or the crack mitigating layer 130 and the substrate 120 are modified such that the article 100 substantially retains its average flexural strength, and the film 110 retains key functional properties for its application.

As understood in this disclosure, the term “film” and the “film 110” can include one or more films, layers, structures and combinations thereof. It should also be understood that for a “film” that includes more than one film, layer, structures, etc., a refractive index associated with the “film” is the aggregate or composite refractive index of the films, layers, structures, etc. that make up the “film.”

Referring to FIG. 1A, aspects of this disclosure include a laminate article 100a including a glass substrate 120 and a crack mitigating layer 130. Within the article, the interfacial properties at an effective interface 140 between the crack mitigating layer 130 and the substrate 120 are modified such that the article 100a substantially retains its average flexural strength.

In one or more embodiments, the laminate articles 100, 100a exhibit functional properties that are also retained after such interface modifications. Functional properties of the film 110 and/or articles 100, 100a may include optical properties, electrical properties and/or mechanical properties, such as hardness, elastic modulus, strain-to-failure, abrasion resistance, scratch resistance, mechanical durability, coefficient of friction, electrical conductivity, electrical resistivity, electron mobility, electron or hole carrier doping, optical refractive index, density, opacity, transparency, reflectivity, absorptivity, transmissivity and the like. In certain implementations, the optical properties of the articles 100, 100a are retained, independent of the properties and/or processing of the crack mitigating layer 130. In one or more embodiments, the refractive index may be measured using an Model 1512-RT analyzer, supplied by n&k Technology, located in San Jose, Calif., or by spectroscopic ellipsometry, as is known in the art. Elastic modulus maybe measured by nanoindentation, using methods known in the art. In certain aspects, the optical transmittance of the substrate 120 and the crack mitigating layer 130 can vary by 1% or less from the optical transmittance of the substrate 120. These functional properties of the articles 100, 100a can be retained after combination with the crack mitigating layer 130, and before any separation of the crack mitigating layer 130 from the glass substrate 120 as described herein.

In one or more embodiments of laminate articles 100, the modification to the effective interface 140 between the film 110 and the glass substrate 120 includes preventing one or more cracks from bridging from one of the film 110 or the glass substrate 120 into the other of the film 110 or the glass substrate 120, while preserving other functional properties of the film 110 and/or the article. In one or more specific embodiments, as illustrated in FIG. 1, the modification of the interfacial properties includes disposing a crack mitigating layer 130 between the glass substrate 120 and the film 110. In one or more embodiments, the crack mitigating layer 130 is disposed on the glass substrate 120 and forms a first interface 150, and the film 110 is disposed on the crack mitigating layer 130 forming a second interface 160. The effective interface 140 includes the first interface 150, the second interface 160 and/or the crack mitigating layer 130.

In certain aspects of the disclosure related to laminate articles 100a (see FIG. 1A), the modification to the effective interface 140 between the crack mitigating layer 130 and the glass substrate 120 includes preventing one or more cracks from bridging from one of the layer 130 or the glass substrate 120 into the other of the layer 130 or the glass substrate 120, while preserving functional properties of the article 100a, particularly those associated with the substrate 120. In one or more specific embodiments, as illustrated in FIG. 1A, the modification of the interfacial properties includes disposing a crack mitigating layer 130 on the glass substrate 120. In one or more embodiments, the crack mitigating layer 130 is disposed on the glass substrate 120 and forms a first interface 150. The effective interface 140 includes the first interface 150 and/or the crack mitigating layer 130

With regard to the laminate articles 100 depicted in FIG. 1, the term “film,” as applied to the film 110 and/or other films incorporated into the article 100, includes one or more layers that are formed by any known method in the art, including discrete deposition or continuous deposition processes. Such layers may be in direct contact with one another. The layers may be formed from the same material or more than one different material. In one or more alternative embodiments, such layers may have intervening layers of different materials disposed therebetween. In one or more embodiments a film may include one or more contiguous and uninterrupted layers and/or one or more discontinuous and interrupted layers (i.e., a layer having different materials formed adjacent to one another).

As used herein (e.g., in relation to laminate articles 100, 100a), the term “dispose” includes coating, depositing and/or forming a material onto a surface using any known method in the art. The disposed material may constitute a layer or film as defined herein. The phrase “disposed on” includes the instance of forming a material onto a surface such that the material is in direct contact with the surface and also includes the instance where the material is formed on a surface, where one or more intervening material(s) is between the disposed material and the surface. The intervening material(s) may constitute a layer or film, as defined herein.

As used herein, the term “average flexural strength” is intended to refer to the flexural strength of a glass-containing material (e.g., an article and/or a glass substrate), as tested through methods such as ring-on-ring, ball-on-ring, or ball drop testing. The term “average” when used in connection with average flexural strength or any other property is based on the mathematical average of measurements of such property on at least 5 samples, at least 10 samples or at least 15 samples or at least 20 samples. Average flexural strength may refer to the scale parameter of two parameter Weibull statistics of failure load under ring-on-ring or ball-on-ring testing. This scale parameter is also called the Weibull characteristic strength, at which a material's failure probability is 63.2%. More broadly, average flexural strength may also be defined by other tests such as a ball drop test, where the glass surface flexural strength is characterized by a ball drop height that can be tolerated without failure. Glass surface strength may also be tested in a device configuration, where an appliance or device containing the glass-containing material (e.g., an article and/or a glass substrate) article is dropped in different orientations that may create a surface flexural stress. Average flexural strength may in some cases also incorporate the strength as tested by other methods known in the art, such as 3-point bend or 4-point bend testing. In some cases, these test methods may be significantly influenced by the edge strength of the article.

As used herein, the terms “bridge,” or “bridging,” refer to crack, flaw or defect formation and such crack, flaw or defect's growth in size and/or propagation from one material, layer or film into another material, layer or film. For example, bridging includes the instance where a crack that is present in the film 110 propagates into another material, layer or film (e.g., the glass substrate 120). The terms “bridge” or “bridging” also include the instance where a crack crosses an interface between different materials, different layers and/or different films. The materials, layers and/or films need not be in direct contact with one another for a crack to bridge between such materials, layers and/or films. For example, the crack may bridge from a first material into a second material, not in direct contact with the first material, by bridging through an intermediate material disposed between the first and second material. The same scenario may apply to layers and films and combinations of materials, layers and films. In the laminate articles 100 described herein, a crack may originate in one of the film 110 or the glass substrate 120 and bridge into the other of the film 110 or the glass substrate 120 across the effective interface 140 (and specifically across the first interface 150 and the second interface 160). Similarly, in the laminate articles 100a, a crack may originate in one of the layer 130 or the glass substrate 120 and bridge into the other of the layer 130 or the glass substrate 120 across the effective interface 140 (and specifically across the first interface 150).

As will be described herein in connection with the laminate articles 100, the crack mitigating layer 130 may deflect cracks from bridging between the film 110 and the glass substrate 120, regardless of where (i.e., the film 110 or the glass substrate 120) the crack originates. Likewise, the crack mitigating layer 130 of the laminate articles 100a may deflect cracks from bridging between the layer 130 and the glass substrate 120. Crack deflection may include at least partial delamination of the crack mitigating layer 130 from the film 110 (in the case of articles 100) and/or glass substrate 120, as described herein, upon bridging of the crack from one material (e.g., the film 110, glass substrate 120 or crack mitigating layer 130) to another material (e.g., the film 110, glass substrate 120 or crack mitigating layer 130). Crack deflection may also include causing a crack to propagate through the crack mitigating layer 130 instead of propagating into the film 110 and/or the glass substrate 120. In such instances, the crack mitigating layer 130 may form a low toughness interface at the effective interface 140 that facilitates crack propagation through the crack mitigating layer instead of into the glass substrate or film. This type of mechanism may be described as deflecting the crack along the effective interface 140.

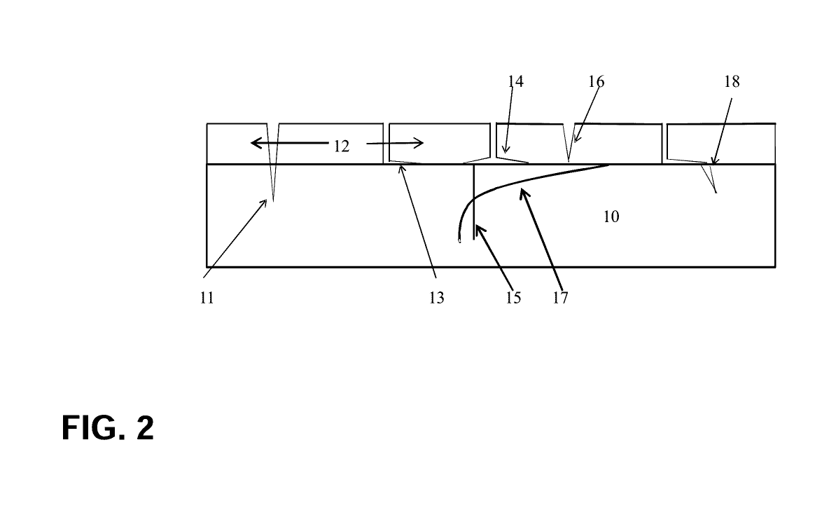

The following theoretical fracture mechanics analysis illustrates selected ways in which cracks may bridge or may be mitigated within a laminated article, e.g., laminate articles 100, 100a. FIG. 2 is a schematic illustrating the presence of a crack in a film disposed on a glass substrate and its possible bridging or mitigation modes. The numbered elements in FIG. 2 are the glass substrate 10, the film 12 on top of a surface (unnumbered) of glass substrate 10, a two-sided deflection 14 into the interface between glass substrate 10 and film 12, an arrest 16 (which is a crack that started to develop in film 12 but did not go completely through film 12), a “kinking” 18 (which is a crack that developed in the surface of film 12, but when it reached the surface of the glass substrate 10 it did not penetrate into the glass substrate 12, but instead moves in a lateral direction as indicated in FIG. 2 and then penetrates the surface of the glass substrate 10 at another position), a penetration crack 11 that developed in the film 12 and penetrated into the glass substrate 10, and a one-sided deflection 13. FIG. 2 also shows a graph of tension vs. compression 17 in the glass substrate 10 compared to zero axis 15. As illustrated, upon application of external loading (in such cases, tensile loading is the most detrimental situation), the flaws in the film can be preferentially activated to form cracks prior to the development of cracks in the residually compressed or strengthened glass substrate. In the scenarios illustrated in FIG. 2, with continued increase of external loading, the cracks will bridge until they encounter the glass substrate. When the cracks reach the surface of glass substrate 10 the possible bridging modes of the crack, when it originates in the film are: (a) penetration into the glass substrate without changing its path as represented by numeral 11; (b) deflection into one side along the interface between the film and the glass substrate as indicated by numeral 13; (c) deflection into two sides along the interface as indicated by numeral 14; (d) first deflection along the interface and then kinking into the glass substrate as indicated by numeral 18; or (e) crack arrest as indicated by numeral 16 due to microscopic deformation mechanisms, for example, plasticity, nano-scale blunting, or nano-scale deflection at the crack tip. Cracks may originate in the film and may bridge into the glass substrate. The above-described bridging modes are also applicable where cracks originate in the glass substrate and bridge into the film, for example where pre-existing cracks or flaws in the glass substrate may induce or nucleate cracks or flaws in the film, thus leading to crack growth or propagation from the glass substrate into the film, resulting in crack bridging.

Crack penetration into the glass substrate 120 and/or film 110 (when present) reduces the average flexural strength of the laminated articles 100, 100a and the glass substrate 120 as compared to the average flexural strength of the glass substrate 120 alone (i.e., without a film or a crack mitigating layer), while crack deflection, crack blunting or crack arrest (collectively referred to herein as crack mitigation) helps retain the average flexural strength of the articles. “Crack blunting” and “crack arrest” can be distinguished from one another. Crack blunting” may comprise an increasing crack tip radius, for example, through plastic deformation or yielding mechanisms. “Crack arrest,” on the other hand, could comprise a number of different mechanisms such as, for example, encountering a highly compressive stress at the crack tip, a reduction of the stress intensity factor at the crack tip resulting from the presence of a low-elastic modulus interlayer or a low-elastic modulus-to-high-elastic modulus interface transition; nano-scale crack deflection or crack tortuosity as in some polycrystalline or composite materials, strain hardening at the crack tip and the like. The various modes of crack deflection will be described herein.

Without being bound by theory, certain possible crack bridging paths can be analyzed in the context of linear elastic fracture mechanics. In the following paragraphs, one crack path is used as an example and the fracture mechanics concept is applied to the crack path to analyze the problem and illustrate the requirements of material parameters to help retain the average flexural strength performance of the article, for a particular range of materials properties.

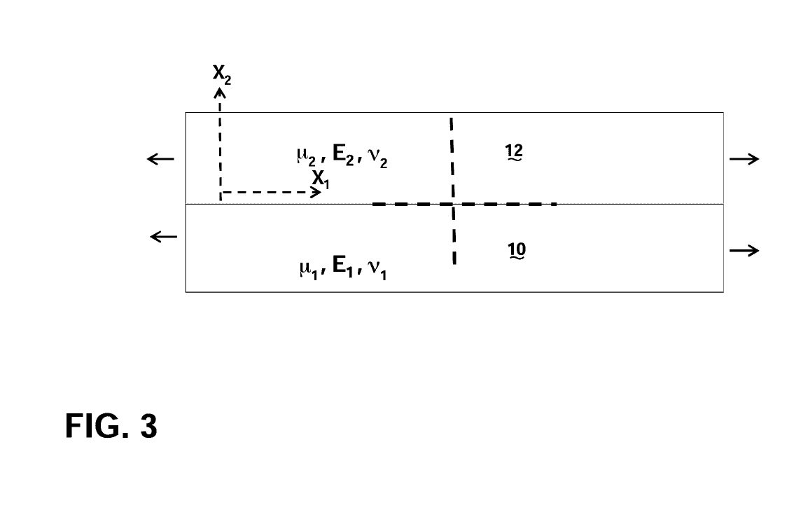

FIG. 3 shows the illustration of the theoretical model framework. This is a simplified schematic view of the interface region between the film 12 and glass substrate 10. The terms μ₁, E₁, v₁, and μ₂, E₂, v₂, are shear modulus, Young's modulus, Poisson's ratio of glass substrate and film materials, Γ_{c}^{Glass} and Γ_{c}^{IT} are critical energy release rate of glass substrate and the interface between substrate and film, respectively.

The common parameters to characterize the elastic mismatch between the film and the substrate are Dundurs' parameters α and β, as defined below

$$α = \frac{{\overline{E}}_{1} - {\overline{E}}_{2}}{{\overline{E}}_{1} + {\overline{E}}_{2}} \qquad ( 1 )$$

where Ē=E/(1−v²) for plain strain and

$$β = \frac{1}{2} \frac{{μ}_{1} ( 1 - 2 {v}_{2} ) - {μ}_{2} ( 1 - 2 {v}_{1} )}{{μ}_{1} ( 1 - {v}_{2} ) + {μ}_{2} ( 1 - {v}_{1} )} \qquad ( 2 )$$

It is worth pointing out that critical energy release rate is closely related with the fracture toughness of the material through the relationship defined as

$$Γ = \frac{1 - {v}^{2}}{E} {K}_{C}^{2} \qquad ( 3 )$$

Under the assumption that there is a pre-existing flaw in the film, upon tensile loading the crack will extend vertically down as illustrated in FIG. 3. Right at the interface, the crack tends to deflect along the interface if

$$\frac{{G}_{d}}{{G}_{p}} \geq \frac{{Γ}_{c}^{IT}}{{Γ}_{c}^{Glass}} \qquad ( 4 )$$

and the crack will penetrate into the glass substrate if

$$\frac{{G}_{d}}{{G}_{p}} \leq \frac{{Γ}_{c}^{IT}}{{Γ}_{c}^{Glass}} \qquad ( 5 )$$

where G_{d} and Gₚ and are the energy release rates of a deflected crack along the interface and a penetrated crack into the glass substrate, respectively. On the left hand side of equations (4) and (5), the ratio G_{d}/Gₚ is a strong function of elastic mismatch parameter α and weakly dependent on β; and on the right hand side, the toughness ratio Γ_{c}^{IT}/δ_{c}^{Glass} is a material parameter.

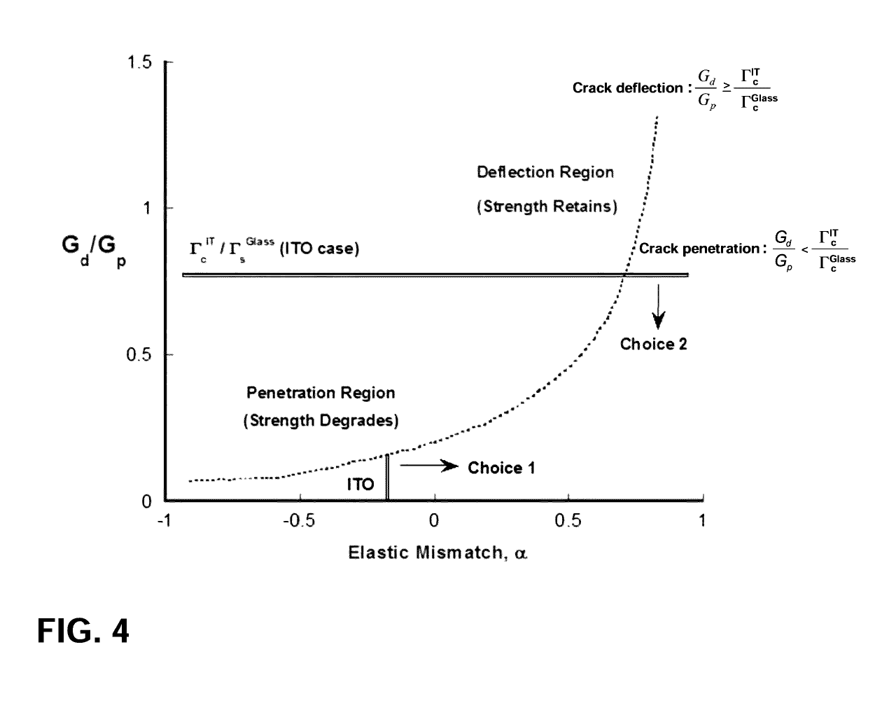

FIG. 4 graphically illustrates the trend of G_{d}/Gₚ as a function of elastic mismatch α, reproduced from a reference for doubly-deflected cracks. (See Ming-Yuan, H. and J. W. Hutchinson, “Crack deflection at an interface between dissimilar elastic materials,” International Journal of Solids and Structures, 1989, 25(9): p. 1053-1067.)

It is evident that the ratio G_{d}/Gₚ is strongly dependent on α. Negative α means the film is stiffer than the glass substrate and positive a means the film is softer than the glass substrate. The toughness ratio Γ_{c}^{IT}/Γ_{c}^{Glass} which is independent of a is a horizontal line in FIG. 4. If the criterion in Equation (4) is satisfied, in FIG. 4, at the region above the horizontal line, the crack tends to deflect along the interface which may be beneficial for the retention of a substrate's average flexural strength. On the other hand, if the criterion in Equation (5) is satisfied, in FIG. 4, at the region below the horizontal line, the crack tends to penetrate into glass substrate which leads to degradation of the average flexural strength of the article, particularly those articles utilizing strengthened or strong glass substrates as described elsewhere herein.

With the above concept, in the following, an indium-tin-oxide (ITO) film is utilized as an illustrative example. For glass substrate, E₁=72 GPa, v₁=0.22, and K_{1c}=0.7 MPa·m^{1/2}; for ITO, E₂=99.8 GPa, and v₂=0.25. (Zeng, K., et al., “Investigation of mechanical properties of transparent conducting oxide thin films.” Thin Solid Films, 2003, 443(1-2): p. 60-65.) The interfacial toughness between the ITO film and glass substrate can be approximately Γᵢₙ=5 J/m², depending on deposition conditions. (Cotterell, B. and Z. Chen, Buckling and cracking of thin films on compliant substrates under compression,” International Journal of Fracture, 2000, 104(2): p. 169-179.) This will give the elastic mismatch α=−0.17 and Γ_{c}^{IT}/Γ_{c}^{Glass}=0.77. These values are plotted in FIG. 4. This fracture analysis predicts that the crack penetration into the glass substrate for the ITO film will be favored, which leads to degradation of the average flexural strength of the glass, particularly glass that is strengthened or strong. This is believed to be one of the potential underlying mechanisms observed with various indium-tin-oxide or other transparent conductive oxide films that are disposed on glass substrates, including strengthened or strong glass substrates. As shown in FIG. 4, one way to mitigate the degradation of the average flexural strength can be to select appropriate materials to change the elastic mismatch α (“Choice 1”) or to adjust the interfacial toughness (“Choice 2”).

The theoretical analysis outlined above suggests that a crack mitigating layer 130 can be used to better retain the strength of laminate articles 100, 100a. Specifically, the insertion of a crack mitigating layer 130 between a glass substrate 120 and a film 110 (for articles 100) or on glass substrate 120 makes crack mitigation, as defined herein, a more preferred path and thus the article is better able to retain its strength. In some embodiments, the crack mitigating layer 130 facilitates crack deflection, as will be described in greater detail herein.

Glass Substrate

Referring to FIGS. 1 and 1A, the laminate articles 100, 100a include a glass substrate 120, which may be strengthened or strong, as described herein, having opposing major surfaces 122, 124. Laminate article 100 also includes a film 110 disposed on a at least one opposing major surface (122 or 124). In addition, laminate articles 100, 100a include a crack mitigating layer 130. With regard to articles 100, the crack mitigating layer 130 is disposed between the film 110 and the glass substrate 120. For articles 100a, the layer 130 is disposed on the substrate 120. In one or more alternative embodiments, the crack mitigating layer 130 and/or the film 110 may be disposed on the minor surface(s) of the glass substrate in addition to or instead of being disposed on at least one major surface (122 or 124).

As used herein, the glass substrate 120 may be substantially planar sheets, although other embodiments may utilize a curved or otherwise shaped or sculpted glass substrate. The glass substrate 120 may be substantially clear, transparent and free from light scattering. The glass substrate may have a refractive index in the range from about 1.45 to about 1.55. In one or more embodiments, the glass substrate 120 may be strengthened or characterized as strong, as will be described in greater detail herein. The glass substrate 120 may be relatively pristine and flaw-free (for example, having a low number of surface flaws or an average surface flaw size less than about 1 micron) before such strengthening. Where strengthened or strong glass substrates 120 are utilized, such substrates may be characterized as having a high average flexural strength (when compared to glass substrates that are not strengthened or strong) or high surface strain-to-failure (when compared to glass substrates that are not strengthened or strong) on one or more major opposing surfaces of such substrates.

Additionally or alternatively, the thickness of the glass substrate 120 may vary along one or more of its dimensions for aesthetic and/or functional reasons. For example, the edges of the glass substrate 120 may be thicker as compared to more central regions of the glass substrate 120. The length, width and thickness dimensions of the glass substrate 120 may also vary according to the article 100 application or use.

The glass substrate 120 according to one or more embodiments includes an average flexural strength that may be measured before and after the glass substrate 120 is combined with the film 110, crack mitigating layer 130 and/or other films or layers. In one or more embodiments described herein, the laminate articles 100, 100a retain their average flexural strength after the combination of the glass substrate 120 with the film 110 (as it pertains to laminate article 100), crack mitigating layer 130 and/or other films, layers or materials, when compared to the average flexural strength of the glass substrate 120 before such a combination. In other words, the average flexural strength of the articles 100, 100a is substantially the same before and after the film 110 (as it pertains to laminate article 100), crack mitigating layer 130 and/or other films or layers are disposed on the glass substrate 120. In one or more embodiments, the articles 100, 100a have an average flexural strength that is significantly greater than the average flexural strength of similar articles that do not include the crack mitigating layer 130 (e.g., a higher strength value than an article that comprises film 110 and glass substrate 120 in direct contact, without an intervening crack mitigating layer 130).

In accordance with one or more embodiments, the glass substrate 120 has an average strain-to-failure that may be measured before and after the glass substrate 120 is combined with the film 110, crack mitigating layer 130 and/or other films or layers. The term “average strain-to-failure” refers to the strain at which cracks propagate without application of additional load, typically leading to catastrophic failure in a given material, layer or film and, perhaps even bridge to another material, layer, or film, as defined herein. Average strain-to-failure may be measured using, for example, ball-on-ring testing. Without being bound by theory, the average strain-to-failure may be directly correlated to the average flexural strength using appropriate mathematical conversions. In specific embodiments, the glass substrate 120, which may be strengthened or strong as described herein, has an average strain-to-failure that is 0.5% or greater, 0.6% or greater, 0.7% or greater, 0.8% or greater, 0.9% or greater, 1% or greater, 1.1% or greater, 1.2% or greater, 1.3% or greater, 1.4% or greater 1.5% or greater or even 2% or greater. In specific embodiments, the glass substrate has an average strain-to-failure of 1.2%, 1.4%, 1.6%, 1.8%, 2.2%, 2.4%, 2.6%, 2.8% or 3% or greater. The average strain-to-failure of the film 110 may be less than the average strain-to-failure of the glass substrate 120 and/or the average strain-to-failure of the crack mitigating layer 130. Without being bound by theory, it is believed that the average strain-to-failure of a glass substrate or any other material is dependent on the surface quality of such material. With respect to glass substrates, the average strain-to-failure of a specific glass substrate is dependent on the conditions of ion exchange or strengthening process utilized in addition to or instead of the surface quality of the glass substrate.

In one or more embodiments, the glass substrate 120 retains its average strain-to-failure after combination with the film 110, crack mitigating layer 130 and/or other films or layers. In other words, the average strain-to-failure of the glass substrate 120 is substantially the same before and after the film 110, crack mitigating layer 130 and/or other films or layers are disposed on the glass substrate 120. In one or more embodiments, the articles 100, 100a have an average strain-to-failure that is significantly greater than the average strain-to-failure of similar articles that do not include the crack mitigating layer 130 (e.g., a higher strain-to-failure than an article that comprises film 110 and glass substrate 120 in direct contact, without an intervening crack mitigating layer). For example, the articles 100, 100a may exhibit average strain-to-failures that are at least 10% higher, 25% higher, 50% higher, 100% higher, 200% higher or 300% higher than the average strain-to-failure of similar articles that do not include the crack mitigating layer 130.

The glass substrate 120 may be provided using a variety of different processes. For instance, example glass substrate forming methods include float glass processes and down-draw processes such as fusion draw and slot draw. In the float glass process, a glass substrate that may be characterized by smooth surfaces and uniform thickness is made by floating molten glass on a bed of molten metal, typically tin. In an example process, molten glass that is fed onto the surface of the molten tin bed forms a floating glass ribbon. As the glass ribbon flows along the tin bath, the temperature is gradually decreased until the glass ribbon solidifies into a solid glass substrate that can be lifted from the tin onto rollers. Once off the bath, the glass substrate can be cooled further and annealed to reduce internal stress.

Down-draw processes produce glass substrates having a uniform thickness that may possess relatively pristine surfaces. Because the average flexural strength of the glass substrate is controlled by the frequency, amount and/or size of surface flaws, a pristine surface that has had minimal contact has a higher initial strength. When this high strength glass substrate is then further strengthened (e.g., chemically), the resultant strength can be higher than that of a glass substrate with a surface that has been lapped and polished. Down-drawn glass substrates may be drawn to a thickness of less than about 2 mm. In addition, down drawn glass substrates may have a very flat, smooth surface that can be used in its final application without costly grinding and polishing.

The fusion draw process, for example, uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass substrate. The fusion draw method offers the advantage that, because the two glass films flowing over the channel fuse together, neither of the outside surfaces of the resulting glass substrate comes in contact with any part of the apparatus. Thus, the surface properties of the fusion drawn glass substrate are not affected by such contact.

The slot draw process is distinct from the fusion draw method. In slot draw processes, the molten raw material glass is provided to a drawing tank. The bottom of the drawing tank has an open slot with a nozzle that extends the length of the slot. The molten glass flows through the slot/nozzle and is drawn downward as a continuous substrate and into an annealing region.

Once formed, glass substrates may be strengthened to form strengthened glass substrates. As used herein, the term “strengthened glass substrate” may refer to a glass substrate that has been chemically strengthened, for example through ion-exchange of larger ions for smaller ions in the surface of the glass substrate. However, other strengthening methods known in the art, such as thermal tempering, may be utilized to form strengthened glass substrates. As will be described, strengthened glass substrates may include a glass substrate having a surface compressive stress in its surface that aids in the strength preservation of the glass substrate. Strong glass substrates are also within the scope of this disclosure and include glass substrates that may not have undergone a specific strengthening process, and may not have a surface compressive stress, but are nevertheless strong. Such strong glass substrates articles may be defined as glass sheet articles or glass substrates having an average strain-to-failure greater than about 0.5%, 0.7%, 1%, 1.5%, or even greater than 2%. Such strong glass substrates can be made, for example, by protecting the pristine glass surfaces after melting and forming the glass substrate. An example of such protection occurs in a fusion draw method, where the surfaces of the glass films do not come into contact with any part of the apparatus or other surface after forming. The glass substrates formed from a fusion draw method derive their strength from their pristine surface quality. A pristine surface quality can also be achieved through etching or polishing and subsequent protection of glass substrate surfaces, and other methods known in the art. In one or more embodiments, both strengthened glass substrates and the strong glass substrates may comprise glass sheet articles having an average strain-to-failure greater than about 0.5%, 0.7%, 1%, 1.5%, or even greater than 2%, for example when measured using ring-on-ring or ball-on-ring flexural testing.

As mentioned above, the glass substrates described herein may be chemically strengthened by an ion exchange process to provide a strengthened glass substrate 120. The glass substrate may also be strengthened by other methods known in the art, such as thermal tempering. In the ion-exchange process, typically by immersion of the glass substrate into a molten salt bath for a predetermined period of time, ions at or near the surface(s) of the glass substrate are exchanged for larger metal ions from the salt bath. In one embodiment, the temperature of the molten salt bath is about 350° C. to 450° C. and the predetermined time period is about two to about eight hours. The incorporation of the larger ions into the glass substrate strengthens the glass substrate by creating a compressive stress in a near surface region or in regions at and adjacent to the surface(s) of the glass substrate. A corresponding tensile stress is induced within a central region or regions at a distance from the surface(s) of the glass substrate to balance the compressive stress. Glass substrates utilizing this strengthening process may be described more specifically as chemically-strengthened glass substrates 120 or ion-exchanged glass substrates 120. Glass substrates that are not strengthened may be referred to herein as non-strengthened glass substrates.

In one example, sodium ions in a strengthened glass substrate 120 are replaced by potassium ions from the molten bath, such as a potassium nitrate salt bath, though other alkali metal ions having larger atomic radii, such as rubidium or cesium, can replace smaller alkali metal ions in the glass. According to particular embodiments, smaller alkali metal ions in the glass can be replaced by Ag⁺ ions. Similarly, other alkali metal salts such as, but not limited to, sulfates, phosphates, halides, and the like may be used in the ion exchange process.

The replacement of smaller ions by larger ions at a temperature below that at which the glass network can relax produces a distribution of ions across the surface(s) of the strengthened glass substrate 120 that results in a stress profile. The larger volume of the incoming ion produces a compressive stress (CS) on the surface and tension (central tension, or CT) in the center of the strengthened glass substrate 120. Depth of exchange may be described as the depth within the strengthened glass substrate 120 (i.e., the distance from a surface of the glass substrate to a central region of the glass substrate), at which ion exchange facilitated by the ion exchange process takes place.

In one embodiment, a strengthened glass substrate 120 can have a surface compressive stress of 300 MPa or greater, e.g., 400 MPa or greater, 450 MPa or greater, 500 MPa or greater, 550 MPa or greater, 600 MPa or greater, 650 MPa or greater, 700 MPa or greater, 750 MPa or greater or 800 MPa or greater. The strengthened glass substrate 120 may have a compressive depth of layer 15 μm or greater, 20 μm or greater (e.g., 25 μm, 30 μm, 35 μm, 40 μm, 45 μm, 50 μm or greater) and/or a central tension of 10 MPa or greater, 20 MPa or greater, 30 MPa or greater, 40 MPa or greater (e.g., 42 MPa, 45 MPa, or 50 MPa or greater) but less than 100 MPa (e.g., 95, 90, 85, 80, 75, 70, 65, 60, 55 MPa or less). In one or more specific embodiments, the strengthened glass substrate 120 has one or more of the following: a surface compressive stress greater than 500 MPa, a depth of compressive layer greater than 15 μm, and a central tension greater than 18 MPa.

Without being bound by theory, it is believed that strengthened glass substrates 120 with a surface compressive stress greater than 500 MPa and a compressive depth of layer greater than about 15 μm typically have greater strain-to-failure than non-strengthened glass substrates (or, in other words, glass substrates that have not been ion exchanged or otherwise strengthened). In some aspects, the benefits of one or more embodiments described herein may not be as prominent with non-strengthened or weakly strengthened types of glass substrates that do not meet these levels of surface compressive stress or compressive depth of layer, because of the presence of handling or common glass surface damage events in many typical applications. However, as mentioned previously, in other specific applications where the glass substrate surfaces can be adequately protected from scratches or surface damage (for example by a protective coating or other layers), strong glass substrates with a relatively high strain-to-failure can also be created through forming and protection of a pristine glass surface quality, using methods such as the fusion forming method. In these alternate applications, the benefits of one or more embodiments described herein can be similarly realized.

Example ion-exchangeable glasses that may be used in the strengthened glass substrate 120 may include alkali aluminosilicate glass compositions or alkali aluminoborosilicate glass compositions, though other glass compositions are contemplated. As used herein, “ion exchangeable” means that a glass substrate is capable of exchanging cations located at or near the surface of the glass substrate with cations of the same valence that are either larger or smaller in size. One example glass composition comprises SiO₂, B₂O₃ and Na₂O, where (SiO₂+B₂O₃)≧66 mol. %, and Na₂O≧9 mol. %. In an embodiment, the glass substrate 120 includes a glass composition with at least 6 wt. % aluminum oxide. In a further embodiment, a glass substrate 120 includes a glass composition with one or more alkaline earth oxides, such that a content of alkaline earth oxides is at least 5 wt. %. Suitable glass compositions, in some embodiments, further comprise at least one of K₂O, MgO, and CaO. In a particular embodiment, the glass compositions used in the glass substrate 120 can comprise 61-75 mol. % SiO₂; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

A further example glass composition suitable for the glass substrate 120, which may optionally be strengthened or strong, comprises: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm Sb₂O₃; where 12 mol. %≦(Li₂O+Na₂O+K₂O)≦20 mol. % and 0 mol. %≦(MgO+CaO)≦10 mol. %.

A still further example glass composition suitable for the glass substrate 120, which may optionally be strengthened or strong, comprises: 63.5-66.5 mol. % SiO₂; 8-12 mol. % Al₂O₃; 0-3 mol. % B₂O₃; 0-5 mol. % Li₂O; 8-18 mol. % Na₂O; 0-5 mol. % K₂O; 1-7 mol. % MgO; 0-2.5 mol. % CaO; 0-3 mol. % ZrO₂; 0.05-0.25 mol. % SnO₂; 0.05-0.5 mol. % CeO₂; less than 50 ppm As₂O₃; and less than 50 ppm Sb₂O₃; where 14 mol. %≦(Li₂O+Na₂O+K₂O)≦18 mol. % and 2 mol. % MgO+CaO)≦7 mol. %.

In a particular embodiment, an alkali aluminosilicate glass composition suitable for the glass substrate 120, which may optionally be strengthened or strong, comprises alumina, at least one alkali metal and, in some embodiments, greater than 50 mol. % SiO₂, in other embodiments at least 58 mol. % SiO₂, and in still other embodiments at least 60 mol. % SiO₂, all as further defined by the ratio given by Equation (6):

$$\frac{{Al}_{2} {O}_{3} + {B}_{2} {O}_{3}}{Σ modifiers} > 1 \qquad ( 6 )$$

and the components are expressed in mol. % and the modifiers are alkali metal oxides. This glass composition, in particular embodiments, comprises: 58-72 mol. % SiO₂; 9-17 mol. % Al₂O₃; 2-12 mol. % B₂O₃; 8-16 mol. % Na₂O; 0-4 mol. % K₂O, and as further defined by Equation (6) above.

In still another embodiment, the glass substrate, which may optionally be strengthened or strong, may include an alkali aluminosilicate glass composition comprising: 64-68 mol. % SiO₂; 12-16 mol. % Na₂O; 8-12 mol. % Al₂O₃; 0-3 mol. % B₂O₃; 2-5 mol. % K₂O; 4-6 mol. % MgO; and 0-5 mol. % CaO, wherein: 66 mol. %≦SiO₂+B₂O₃+CaO≦69 mol. %; Na₂O+K₂O+B₂O₃+MgO+CaO+SrO>10 mol. %; 5 mol. %≦MgO+CaO+SrO≦8 mol. %; (Na₂O+B₂O₃)−Al₂O₃≦2 mol. %; 2 mol. %≦Na₂O−Al₂O₃≦6 mol. %; and 4 mol. %≦(Na₂O+K₂O)−Al₂O₃≦10 mol. %.

In some embodiments, the glass substrate 120, which may optionally be strengthened or strong, may comprise an alkali silicate glass composition comprising: 2 mol % or more of Al₂O₃ and/or ZrO₂, or 4 mol % or more of Al₂O₃ and/or ZrO₂.

In some embodiments, the glass substrate used in the glass substrate 120 may be batched with 0-2 mol % of at least one fining agent selected from a group that includes Na₂SO₄, NaCl, NaF, NaBr, K₂SO₄, KCl, KF, KBr, and SnO₂.

The glass substrate 120 according to one or more embodiments can have a thickness ranging from about 50 μm to 5 mm. Example glass substrate 120 thicknesses range from 100 μm to 500 μm, e.g., 100, 200, 300, 400 or 500 μm. Further example glass substrate 120 thicknesses range from 500 μm to 1000 μm, e.g., 500, 600, 700, 800, 900 or 1000 μm. The glass substrate 120 may have a thickness greater than 1 mm, e.g., about 2, 3, 4, or 5 mm. In one or more specific embodiments, the glass substrate 120 may have a thickness of 2 mm or less or less than 1 mm. The glass substrate 120 may be acid polished or otherwise treated to remove or reduce the effect of surface flaws.

Film

The laminate article 100 (see FIG. 1) includes a film 110 disposed on a surface of the glass substrate 120 and specifically on the crack mitigating layer 130. The film 110 may be disposed on one or both major surfaces 122, 124 of the glass substrate 120. In one or more embodiments, the film 110 may be disposed on one or more minor surfaces (not shown) of the glass substrate 120 in addition to or instead of being disposed on one or both major surfaces 122, 124. In one or more embodiments, the film 110 is free of macroscopic scratches or defects that are easily visible to the eye. The film 110 forms the effective interface 140 with the glass substrate 120.

In one or more embodiments, the film 110 may lower the average flexural strength of laminate articles 100 incorporating such films and glass substrate, through the mechanisms described herein. In one or more embodiments, such mechanisms include instances in which the film may lower the average flexural strength of the article because crack(s) developing in such film bridge into the glass substrate. In other embodiments, the mechanisms include instances in which the film may lower the average flexural strength of the article because cracks developing in the glass substrates bridge into the film. The film of one or more embodiments may exhibit a strain-to-failure of 2% or less or a strain-to-failure that is less than the strain to failure of the glass substrates described herein. Films including any of these attributes may be characterized as brittle.

In accordance with one or more embodiments, the film 110 may have a strain-to-failure (or crack onset strain level) that is lower than the strain-to-failure of the glass substrate 120. For example, the film 110 may have a strain-to-failure of about 2% or less, about 1.8% or less, about 1.6% or less, about 1.5% or less, about 1.4% or less, about 1.2% or less, about 1% or less, about 0.8% or less, about 0.6% or less, about 0.5% or less, about 0.4% or less or about 0.2% or less. In some embodiments, the strain-to-failure of the film 110 may be lower than that the strain-to-failure of the strengthened glass substrates 120 that have a surface compressive stress greater than 500 MPa and a compressive depth of layer greater than about 15 μm. In one or more embodiments, the film 110 may have a strain-to-failure that is at least 0.1% lower or less, or in some cases, at least 0.5% lower or less than the strain-to-failure of the glass substrate 120. In one or more embodiments, the film 110 may have a strain-to-failure that is at least about 0.15%, 0.2%, 0.25%, 0.3%, 0.35%, 0.4%, 0.45%, 0.55%, 0.6%, 0.65%, 0.7%, 0.75%, 0.8%, 0.85%, 0.9%, 0.95% or 1% lower or less than the strain-to-failure of the glass substrate 120. These strain-to-failure values can be measured, for example, using ball-on-ring flexural test methods combined with optional microscopic or high-speed-camera analysis. In some cases, the onset of film cracking may be measured by analyzing the electrical resistivity of a conducting film. These various analyses can be performed during the application of load or stress, or in some cases after the application of load or stress.

Exemplary films 110 may have an elastic modulus of at least 25 GPa and/or a hardness of at least 1.75 GPa, although some combinations outside of this range are possible. In some embodiments the film 110 may have an elastic modulus 50 GPa or greater or even 70 GPa or greater. For example, the film elastic modulus may be 55 GPa, 60 GPa, 65 GPa, 75 GPa, 80 GPa, 85 GPa or more. In one or more embodiments, the film 110 may have a hardness greater than 3.0 GPa. For example, the film 110 may have a hardness of 5 GPa, 5.5 GPa, 6 GPa, 6.5 GPa, 7 GPa, 7.5 GPa, 8 GPa, 8.5 GPa, 9 GPa, 9.5 GPa, 10 GPa or greater. These elastic modulus and hardness values can be measured for such films 110 using known diamond nano-indentation methods that are commonly used for determining the elastic modulus and hardness of films. Exemplary diamond nano-indentation methods may utilize a Berkovich diamond indenter.

The films 110 described herein may also exhibit a fracture toughness of less than about 10 MPa·m^{1/2}, or in some cases less than 5 MPa·m^{1/2}, or in some cases less than 1 MPa·m^{1/2}. For example, the film may have a fracture toughness of 4.5 MPa·m^{1/2}, 4 MPa·m^{1/2}, 3.5 MPa·m^{1/2}, 3 MPa·m^{1/2}, 2.5 MPa·m^{1/2}, 2 MPa·m^{1/2}, 1.5 MPa·m^{1/2}, 1.4 MPa·m^{1/2}, 1.3 MPa·m^{1/2}, 1.2 MPa·m^{1/2}, 1.1 MPa·m^{1/2}, 0.9 MPa·m^{1/2}, 0.8 MPa·m^{1/2}, 0.7 MPa·m^{1/2}, 0.6 MPa·m^{1/2}, 0.5 MPa·m^{1/2}, 0.4 MPa·m^{1/2}, 0.3 MPa·m^{1/2}, 0.2 MPa·m^{1/2}, 0.1 MPa·m^{1/2} or less.

The films 110 described herein may also have a critical strain energy release rate (G_{IC}=K_{IC}²/E) that is less than about 0.1 kJ/m², or in some cases less than 0.01 kJ/m². In one or more embodiments, the film 110 may have a critical strain energy release rate of 0.09 kJ/m², 0.08 kJ/m², 0.07 kJ/m², 0.06 kJ/m², 0.05 kJ/m², 0.04 kJ/m², 0.03 kJ/m², 0.02 kJ/m², 0.0075 kJ/m², 0.005 kJ/m², 0.0025 kJ/m² or less.

In one or more embodiments, the film 110 may include a plurality of layers, each with the same or different thicknesses. In certain aspects, one or more layers within the film may have a different composition than the other layers in film 110. Various sequences of layers making up film 110 are also contemplated by certain aspects of the disclosure. In one or more embodiments, each of the layers of the film may be characterized as brittle based on one or more of the layer's impact on the average flexural strength of the article 100 and/or the layer's strain-to-failure, fracture toughness, or critical strain energy release rate values, as otherwise described herein. In one variant, the layers of the film 110 need not have identical properties such as elastic modulus and/or fracture toughness. In another variant, the layers of the film 110 may include different materials from one another—e.g., as in alternating, thin layers having different compositions.

The compositions or material(s) of the film 110 are not particularly limited. Some non-limiting examples of film 110 materials include oxides such as SiO₂, Al₂O₃, TiO₂, Nb₂O₅, Ta₂O₅; oxynitrides such as SiOₓN_{y}, SiAlₓO_{y}N_{z}, and AlOₓN_{y}; nitrides such as SiNₓ, AlNₓ, cubic boron nitride, and TiNₓ; carbides such as SiC, TiC, and WC; combinations of the above such as oxycarbides and oxy-carbo-nitrides (for example, SiCₓO_{y} and SiCₓO_{y}N_{z}); semiconductor materials such as Si and Ge; transparent conductors such as indium-tin-oxide (ITO), tin oxide, fluorinated tin oxide, aluminum zinc oxide, or zinc oxide; carbon nanotube or graphene-doped oxides; silver or other metal-doped oxides, highly siliceous polymers such as highly cured siloxanes and silsesquioxanes; diamond or diamond-like-carbon materials; or selected metal films which can exhibit a fracture behavior.

The film 110 can be disposed on the glass substrate 120 by vacuum deposition techniques, for example, chemical vapor deposition (e.g., plasma enhanced chemical vapor deposition, atmospheric pressure chemical vapor deposition, or plasma-enhanced atmospheric pressure chemical vapor deposition), physical vapor deposition (e.g., reactive or nonreactive sputtering or laser ablation), thermal, resistive, or e-beam evaporation, or atomic layer deposition. The film 110 may also be disposed on one or more surfaces 122, 124 of the glass substrate 120 using liquid-based techniques, for example sol-gel coating or polymer coating methods, for example spin, spray, slot draw, slide, wire-wound rod, blade/knife, air knife, curtain, gravure, and roller coating among others. In some embodiments it may be desirable to use adhesion promoters, such as silane-based materials, between the film 110 and the glass substrate 120, between the glass substrate 120 and crack mitigating layer 130, between the layers (if any) of the crack mitigating layer 130, between the layers (if any) of the film 110 and/or between the film 110 and the crack mitigating layer 130. In one or more alternative embodiments, the film 110 may be disposed on the glass substrate 120 as a transfer layer.

The film 110 thickness can vary depending on the intended use of the article 100. In one embodiment the film 110 thickness may be in the ranges from about 0.005 μm to about 0.5 μm or from about 0.01 μm to about 20 μm. In another embodiment, the film 110 may have a thickness in the range from about 0.05 μm to about 10 μm, from about 0.05 μm to about 0.5 μm, from about 0.01 μm to about 0.15 μm or from about 0.015 μm to about 0.2 μm.

In some embodiments, it may be advantageous to include a material (or materials) in the film 110 (e.g., as comprising a single layer, dual-layer or multi-layer structure) that has:

(1) a refractive index that is similar to (or greater than) the refractive index of either the glass substrate 120, the crack mitigating layer 130 and/or other films or layers in order to minimize optical interference effects;

(2) a refractive index (real and/or imaginary components) that is tuned to achieve anti-reflective interference effects; and/or

(3) a refractive index (real and/or imaginary components) that is tuned to achieve wavelength-selective reflective or wavelength-selective absorptive effects, such as to achieve UV or IR blocking or reflection, or to achieve coloring/tinting effects.

In one or more embodiments, the film 110 may have a refractive index that is greater than the refractive index of the glass substrate 120 and/or greater than the refractive index of the crack mitigating layer 130. In one or more embodiments, the film may have a refractive index in the range from about 1.7 to about 2.2, or in the range from about 1.4 to about 1.6, or in the range from about 1.6 to about 1.9. In should be understood, however, that certain aspects of the disclosure can employ a film 110 having one or more layers in which such layer(s) have a refractive index comparable to that of the substrate, even if the aggregate refractive index of the film exceeds that of the substrate (e.g., a film 110 with one more silica layers and a balance of silicon nitride layer(s) disposed over a substrate 120 having a silicate glass composition).

The film 110 may also serve multiple functions, or be integrated with additional film(s) or layers as described herein that serve other functions than the film 110 or even the same function(s) as the film 110. The film 110 may include UV or IR light reflecting or absorbing layers, anti-reflection layers, anti-glare layers, dirt-resistant layers, self-cleaning layers, scratch-resistant layers, barrier layers, passivation layers, hermetic layers, diffusion-blocking layers, fingerprint-resistant layers, and the like. Further, the film 110 may include conducting or semi-conducting layers, thin film transistor layers, EMI shielding layers, breakage sensors, alarm sensors, electrochromic materials, photochromic materials, touch sensing layers, or information display layers. The film 110 and/or any of the foregoing layers may include colorants or tint. When information display layers are integrated into the article 100, the article 100 may form part of a touch-sensitive display, a transparent display, or a heads-up display. It may be desirable that the film 110 performs an interference function, which selectively transmits, reflects, or absorbs different wavelengths or colors of light. For example, the films 110 may selectively reflect a targeted wavelength in a heads-up display application.

Functional properties of the film 110 may include optical properties, electrical properties and/or mechanical properties, such as hardness, elastic modulus, strain-to-failure, abrasion resistance, mechanical durability, coefficient of friction, electrical conductivity, electrical resistivity, electron mobility, electron or hole carrier doping, optical refractive index, density, opacity, transparency, reflectivity, absorptivity, transmissivity and the like. These functional properties are substantially maintained or even improved after the film 110 is combined with the glass substrate 120, crack mitigating layer 130 and/or other films included in the article 100.

Crack Mitigating Layer

As described herein, the crack mitigating layer 130 provides a moderate adhesion energy at the effective interface 140 in laminate articles 100, 100a. The crack mitigating layer 130 provides a moderate adhesion energy by forming a low toughness layer at the effective interface 140 that facilitates crack deflection into the crack mitigating layer instead of the film 110 (when present) or glass substrate 120. The crack mitigating layer 130 may also provide a moderate adhesion energy value by forming a low toughness interface. The low toughness interface is characterized by delamination of the crack mitigating layer 130 from the glass substrate 120 or film 110 upon application of a specified load. This delamination causes cracks to deflect along either the first interface 150 or the second interface 160 (e.g., for laminate articles 100 when a film 110 is present over the crack mitigating layer 130). With regard to articles 100, cracks may also deflect along a combination of the first and second interfaces 150 and 160, for example following a path which may cross over from one interface to the other.

In one or more embodiments, crack mitigating layer 130 provides moderate adhesion by modifying the effective adhesion energy at the effective interface 140, e.g., between the glass substrate 120 and the film 110 for articles 100 and between the layer 130 and the substrate 120 for articles 100a. In one or more specific embodiments, one or both of the first interface 150 and the second interface 160 exhibit the effective adhesion energy. In one or more embodiments, the effective adhesion energy may be about 5 J/m² or less, about 4.5 J/m² or less, about 4 J/m² or less, about 3.5 J/m² or less, about 3 J/m² or less, about 2.5 J/m² or less, about 2 J/m² or less, about 1.5 J/m² or less, about 1 J/m² or less or about 0.85 J/m² or less. The lower limit of the effective adhesion energy may be about 0.1 J/m² or about 0.01 J/m². In one or more embodiments, the effective adhesion energy at one or more of the first interface and the second interface may be in the range from about 0.85 J/m² to about 3.85 J/m², from about 0.85 J/m² to about 3 J/m², from about 0.85 J/m² to about 2 J/m², and from about 0.85 J/m² to about 1 J/m². The effective adhesion energy at one or more of the first interface 150 and the second interface 160 can also be between about 0.1 J/m² and about 0.85 J/m², or between about 0.3 J/m² and about 0.7 J/m². According to some embodiments, the effective adhesion energy at one or more of the first interface and the second interface remains substantially constant, or within a target range such as from 0.1 J/m² and about 0.85 J/m², from ambient temperature up to about 600° C. In some embodiments, the effective adhesion energy at one or more of the interfaces is at least 25% less than the average cohesive adhesion energy of the glass substrate from ambient temperature up to about 600° C.

In embodiments of laminate articles 100, 100a (see FIGS. 1 and 1A) in which the effective interface, 140, the first interface 150 and/or the second interface 160 exhibits moderate adhesion, at least a portion of the crack mitigating layer 130 may separate from the glass substrate and/or the film during a loading process that causes crack growth and/or crack formation in the film and/or the crack mitigating layer. When at least a portion of the crack mitigating layer 130 separates from the glass substrate 120 and/or the film 110, such separation may include a reduced adhesion or no adhesion between the crack mitigating layer and the glass substrate 120 and/or film 110 from which the crack mitigating layer separates. In other embodiments, when only a portion of the crack mitigating layer separates, such a separated portion may be surrounded completely or at least partially by portions of the crack mitigating layer still adhered to the glass substrate 120 and/or film 110. In one or more embodiments, at least a portion of the crack mitigating layer 130 may separate from one of the film 110 or the glass substrate 120 when the laminated article is strained at a specified strain level during such loading. In one or more embodiments, the strain level may be between the first average strain-to-failure of the glass substrate 120 and the average strain-to-failure of the film 110.

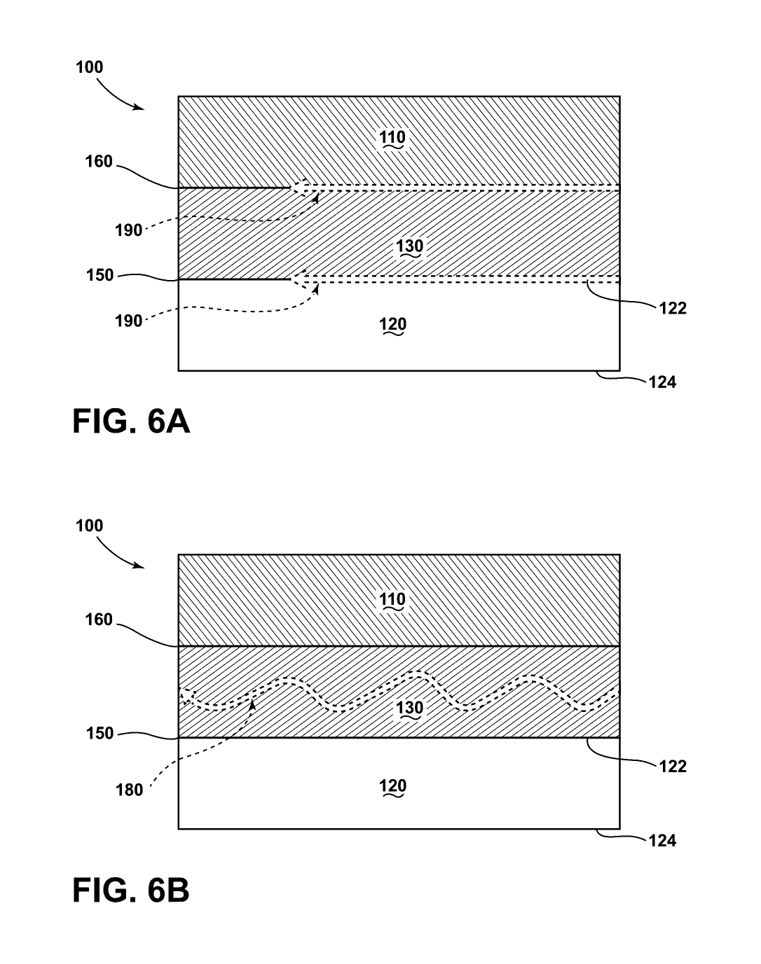

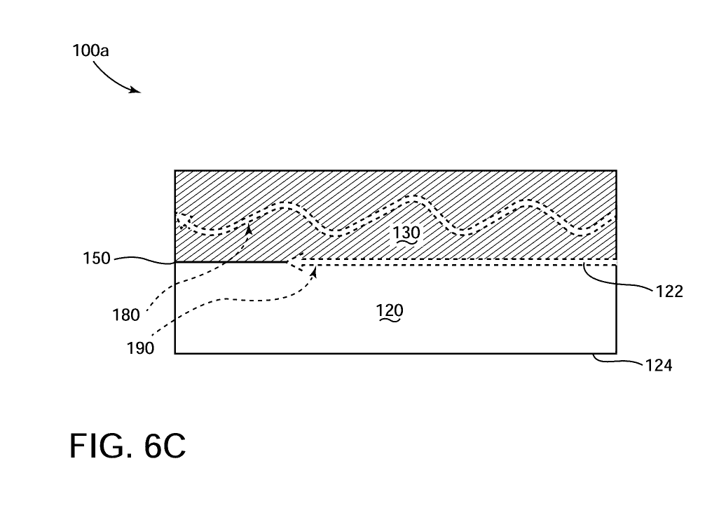

In one or more specific embodiments of laminate article 100, at least a portion of the crack mitigating layer 130 separates from the film 110 when a crack originating in the film 110 bridges into the crack mitigating layer 130 (or crosses the second interface 160). In a particular embodiment of the article 100, at least a portion of the crack mitigating layer 130 separates from the film 110 as an adhesive failure 190 at the interface 160 (see FIG. 6A) when a crack originating in the film 110 bridges into the crack mitigating layer 130. In other embodiments of laminate articles 100 and 100a, at least a portion of the crack mitigating layer 130 separates from the glass substrate 120 when a crack originating in the glass substrate 120 bridges into the crack mitigating layer 130 (or crosses the first interface 150) (see FIGS. 6A and 6C). In another particular embodiment, at least a portion of the crack mitigating layer 130 separates from the glass substrate 120 as an adhesive failure 190 at the interface 150 (see FIGS. 6A and 6C) when a crack originating in the glass substrate 120 bridges into the crack mitigating layer 130. As used herein, the term “adhesive failure” relates to crack propagation substantially confined to one or more of the interfaces 150 and 160 between the crack mitigating layer 130, the film 110 and the glass substrate 120 of the articles 100, 100a.

The crack mitigating layer 130 does not separate and remains adhered to the glass substrate 120 (and the film 110 for articles 100) at load levels that do not cause crack growth and/or crack formation (i.e., at average strain-to-failure levels less than the average strain-to-failure of the glass substrate and less than the average strain-to-failure of the film). Without being bound by theory, delamination or partial delamination of the crack mitigating layer 130 reduces the stress concentrations in the glass substrate 120. Accordingly, it is believed that a reduction in stress concentrations in the glass substrate 120 causes an increase in the load or strain level that is required for the glass substrate 120 (and ultimately the laminated articles 100, 100a) to fail. In this manner, the crack mitigating layer 130 prevents a decrease or increases the average flexural strength of the laminated article, as compared to laminated articles without the crack mitigating layer.

The material and thickness of the crack mitigating layer 130 can be used to control the effective adhesion energy between glass substrate 120 and/or the film 110. In general, the adhesion energy between two surfaces is given by (see L. A. Girifalco and R. J. Good, “A theory for the estimation of surface and interfacial energies, I. derivation and application to interfacial tension,” Journal of Physical Chemistry, vol. 61, p. 904 (“Girifalco and Good”)):

W=⊕₁+γ₂−γ₁₂ (7)

where γ₁, γ₂ and γ₁₂ are the surface energies of surface 1, surface 2 and the interfacial energy of surface 1 and 2 respectively. The individual surface energies are usually a combination of two terms: a dispersion component γ^{d} and a polar component γ^{p} given by:

γ=γ^{d}+γ^{p} (8)

When the adhesion is mostly due to London dispersion forces (γ^{d}) and polar forces for example hydrogen bonding (γ^{p}), the interfacial energy could be given by (see Girifalco and Good):

γ₁₂=γ₁+γ₂−2\sqrt{γ₁^{d}γ₂^{d}}−\sqrt{2γ₁^{p}γ₂^{p}} (9)

After substituting (9) in (7), the energy of adhesion could be approximately calculated as:

w˜2[\sqrt{γ₁^{d}γ₂^{d}}+\sqrt{γ₁^{p}γ₂^{p}}] (10)

In the above equation (10), only van der Waal (and/or hydrogen bonding) components of adhesion energies are considered. These include polar-polar interaction (Keesom), polar-non polar interaction (Debye) and nonpolar-nonpolar interaction (London). However, other attractive energies may also be present, for example covalent bonding and electrostatic bonding. So, in a more generalized form, the above equation is written as:

w˜2[\sqrt{γ₁^{d}γ₂^{d}}+\sqrt{γ₁^{p}γ₂^{p}}]+w_{c}+wₑ (11)

where w_{c} and wₑ are the covalent and electrostatic adhesion energies. Equation (11) describes that the adhesion energy is a function of four surface energy parameters plus the covalent and electrostatic energy, if any. An appropriate adhesion energy can be achieved by choice of crack mitigating layer 130 material(s) to control van der Waals (and/or hydrogen) bonding and/or covalent bonding.

The adhesive energy of thin films is challenging to directly measure, including the adhesive energy between the crack mitigating layer 130 and the glass substrate 120 or film 110. In contrast, the bond strength of the bond between two pieces of glass can be determined by inserting a thin blade and measuring the crack length. In the case of a thin glass bonded to a thicker carrier with a coating or surface modification, the bond adhesion energy γ is related to the carrier Young's modulus E₁, carrier thickness t_{w1}, thin glass modulus E₂, thin glass thickness t_{w2}, blade thickness t_{b}, and crack length L by the following equation, given by Equation (12) below.

$$γ = \frac{3 {t}_{b}^{2} {E}_{1} {t}_{w 1}^{3} {E}_{2} {t}_{w 2}^{3}}{16 {L}^{4} ( {E}_{1} {t}_{w 1}^{3} + {E}_{2} {t}_{w 2}^{3} )} \qquad ( 12 )$$

Equation (12) can be employed to approximate the adhesive energy between the crack mitigating layer 130 and the glass substrate 120 or film 110 (e.g., the adhesive energy at the interfaces 150 and 160, respectively, for laminate article 100 depicted in FIG. 1; and the adhesive energy at the interface 150 for laminate article 100a depicted in FIG. 1A). For example, the adhesive energy between two glass substrates (e.g., one thick and one thin) can be measured using Equation (12) as a control. Various glass substrate samples can then be prepared by conducting a surface treatment to a control glass substrate (e.g., a thick carrier substrate). The surface treatment is exemplary of a particular crack mitigating film 130. After the surface treatment, the treated glass substrate is then bonded to a thin glass substrate comparable to the thin substrates employed as the control. The adhesive energy for the treated samples can then be measured using Equation (12) and then compared to the results obtained from comparable measurements to the glass control samples.

In one or more embodiments of the laminated articles 100 and 100a, the crack mitigating layer 130 may form a preferred path of crack propagation other than bridging between the film 110 and the glass substrate 120. In other words, the crack mitigating layer 130 may deflect a crack forming in one of the film 110 and the glass substrate 120 and propagating toward the other of the film 110 and the glass substrate 120 into the crack mitigating layer 130. In such embodiments, the crack may propagate through the crack mitigating layer 130 in a direction substantially parallel to at least one of the first interface 150 or the second interface 160 for laminate articles 100 and substantially parallel to the first interface 150 for laminate articles 100a. As depicted in FIGS. 6B and 6C, the crack becomes a cohesive failure 180, confined within the crack mitigating layer 130. As used herein, the term “cohesive failure” relates to crack propagation substantially confined within the crack mitigating layer 130.

The crack mitigating layer 130, when configured to develop a cohesive failure 180 as shown in FIGS. 6B and 6C, provides a preferred path for crack propagation in such embodiments. The crack mitigating layer 130 may cause a crack originating in the film 110 or the glass substrate 120 and entering into the crack mitigating layer 130 to remain in the crack mitigating layer. Alternatively, or additionally, the crack mitigating layer 130 of laminate article 100 effectively confines a crack originating in one of the film 110 and glass substrate 120 from propagating into the other of such film and glass substrate. Similarly, the crack mitigating layer 130 of laminate article 100a effectively confines a crack originating in one of the layer 130 and glass substrate 120 from propagating into the other such layer and substrate. These behaviors may be characterized individually or collectively as crack deflection. In this way, the crack is deflected from bridging between the film 110 and the glass substrate 120, or between the crack mitigating layer 130 and the glass substrate 120. In one or more embodiments, the crack mitigating layer 130 may provide a low toughness layer or interface that exhibits a low fracture toughness and/or a low critical strain energy release rate, which may promote crack deflection into the crack mitigating layer 130 instead of through the crack mitigating layer into the film 110 and/or glass substrate 120. As used herein, “facilitate” includes creating favorable conditions in which the crack deflects into the crack mitigating layer 130 instead of propagating into the glass substrate 120 or the film 110. “Facilitate” may also include creating a less tortuous path for crack propagation into and/or through the crack mitigating layer 130 instead of into the glass substrate 120 or the film 110.

The crack mitigating layer 130 may exhibit a relatively low fracture toughness to provide a low toughness crack mitigating layer, as will be described in greater detail below. In such embodiments, the crack mitigating layer 130 may exhibit a fracture toughness that is about 50% or less than 50% of the fracture toughness of either the glass substrate 120 or the film 110. In more specific embodiments, the fracture toughness of the crack mitigating layer 130 may be about 25% or less than 25% of the fracture toughness of either the glass substrate 120 or the film 110. For example, the crack mitigating layer 130 may exhibit a fracture toughness of about 1 MPa·m^{1/2} or less, 0.75 MPa·m^{1/2} or less, 0.5 MPa·m^{1/2} or less, 0.4 MPa·m^{1/2} or less, 0.3 MPa·m^{1/2} or less, 0.25 MPa·m^{1/2} or less, 0.2 MPa·m^{1/2} or less, 0.1 MPa·m^{1/2} or less, and all ranges and sub-ranges between the foregoing values.

In accordance with one or more embodiments of the article 100, the crack mitigating layer 130 may have an average strain-to-failure that is greater than the average strain-to-failure of the film 110. In one or more embodiments of laminate articles 100 and 100a, the crack mitigating layer 130 may have an average strain-to-failure that is equal to or greater than about 0.5%, 0.7%, 1%, 1.5%, 2%, or even 4%. The crack mitigating layer 130 may have an average strain-to-failure of 0.6%, 0.8%, 0.9%, 1.1%, 1.2%, 1.3%, 1.4%, 1.6%, 1.7%, 1.8%, 1.9%, 2.2%, 2.4%, 2.6%, 2.8%, 3%, 3.2%, 3.4%, 3.6%, 3.8%, 4%, 5% or 6% or greater. In one or more embodiments, the film 110 may have an average strain-to-failure (crack onset strain) that is 1.5%, 1.0%, 0.7%, 0.5%, or even 0.4% or less. The film 110 may have an average strain-to-failure of 1.4%, 1.3%, 1.2%, 1.1%, 0.9%, 0.8%, 0.6%, 0.3%, 0.2%, 0.1% or less. The average strain-to-failure of the glass substrate 120 may be greater than the average strain-to-failure of the film 110 for laminate articles 100, and in some instances, may be greater than the average strain-to-failure of the crack mitigating layer 130. In some other specific embodiments of laminated articles 100 and 100a, the crack mitigating layer 130 may have a higher average strain-to-failure than the glass substrate 120, to minimize any negative mechanical effect of the crack mitigating layer on the glass substrate.

The crack mitigating layer 130 according to one or more embodiments may have a critical strain energy release rate (G_{IC}=K_{IC}²/E) that is greater than the critical strain energy release rate of the film 110. In other examples, the crack mitigating layer 130 may exhibit a critical strain energy release rate that is less than 0.25 times or less than 0.5 times the critical strain energy release rate of the glass substrate. In specific embodiments, the critical strain energy release rate of the crack mitigating layer 130 can be about 0.1 kJ/m² or less, about 0.09 kJ/m² or less, about 0.08 kJ/m² or less, about 0.07 kJ/m² or less, about 0.06 kJ/m² or less, about 0.05 kJ/m² or less, about 0.04 kJ/m² or less, about 0.03 kJ/m² or less, about 0.02 kJ/m² or less, about 0.01 kJ/m² or less, about 0.005 kJ/m² or less, about 0.003 kJ/m² or less, about 0.002 kJ/m² or less, about 0.001 kJ/m² or less; but in some embodiments, greater than about 0.0001 kJ/m² (i.e., greater than about 0.1 J/m²).

The crack mitigating layer 130 employed in laminate articles 100, 100a may have a refractive index that is greater than the refractive index of the glass substrate 120. In one or more embodiments, the refractive index of the crack mitigating layer 130 may be less than the refractive index of the film 110. In a more specific embodiment, the refractive index of the crack mitigating layer 130 may be between the refractive index of the glass substrate 120 and the film 110. For example, the refractive index of the crack mitigating layer 130 may be in the range from about 1.45 to about 1.95, from about 1.5 to about 1.8, or from about 1.6 to about 1.75. Alternatively, the crack mitigating layer may have a refractive index that is substantially the same as the glass substrate, or a refractive index that is not more than 0.05 index units greater than or less than the glass substrate over a substantial portion of the visible wavelength range (e.g. from 450 to 650 nm). In certain implementations, the crack mitigating layer 130 is configured such that the optical transmittance of the substrate and the crack mitigating layer vary by 1% or less from the optical transmittance of the substrate alone. Put another way, the crack mitigating layer 130 can be configured such that the optical properties (e.g., optical transmittance and reflectance) of the substrate are retained.

In one or more embodiments, the crack mitigating layer 130 of the laminate articles 100, 100a is able to withstand high temperature processes. Such processes can include vacuum deposition processes such as chemical vapor deposition (e.g., plasma-enhanced chemical vapor deposition), physical vapor deposition (e.g., reactive or nonreactive sputtering or laser ablation), thermal or e-beam evaporation and/or atomic layer deposition. In one or more specific embodiments, the crack mitigating layer 130 is able to withstand a vacuum deposition process in which the film 110 and/or other films disposed on the glass substrate 120 are deposited on the crack mitigating layer 130 via vacuum deposition. As used herein, the term “withstand” includes the resistance of the crack mitigating layer 130 to temperatures exceeding 100° C., 200° C., 300° C., 400° C., 500° C., 600° C. and potentially even greater temperatures. In some embodiments, the crack mitigating layer 130 may be considered to withstand the vacuum deposition or temperature treatment process if the crack mitigating layer 130 experiences a weight loss of 10% or less, 8% or less, 6% or less, 4% or less, 2% or less or 1% or less, after deposition of the film 110 and/or other films on the glass substrate (and on the crack mitigating layer 130). The deposition process (or testing after the deposition process) under which the crack mitigating layer experiences weight loss can include temperatures of about 100° C. or greater, 200° C. or greater, 300° C. or greater, 400° C. or greater; environments that are rich in a specific gas (e.g., oxygen, nitrogen, argon etc.); and/or environments in which deposition may be performed under high vacuum (e.g. 10⁻⁶ Torr), under atmospheric conditions and/or at pressures therebetween (e.g., 10 mTorr). As will be discussed herein, the material utilized to form the crack mitigating layer 130 may be specifically selected for its high temperature tolerance (i.e., the ability to withstand high temperature processes such as vacuum deposition processes) and/or its environmental tolerance (i.e., the ability to withstand environments rich in a specific gas or at a specific pressure). These tolerances may include high temperature tolerance, high vacuum tolerance, low vacuum outgassing, a high tolerance to plasma or ionized gases, a high tolerance to ozone, a high tolerance to UV, a high tolerance to solvents, or a high tolerance to acids or bases. In some instances, the crack mitigating layer 130 may be selected to pass an outgassing test according to ASTM E595. In one or more embodiments, the laminate article 100, 100a including the crack mitigating layer 130 may exhibit an improved average flexural strength over articles without the crack mitigating layer 130. In other words, articles 100 that include a glass substrate 120, a film 110 and a crack mitigating layer 130 and articles 100 that include a glass substrate 120 and a crack mitigating layer 130 both exhibit greater average flexural strength than articles that include the glass substrate 120 and the film 110 but no crack mitigating layer 130 and articles that include the glass substrate but no crack mitigating layer 130, respectively.

In one or more embodiments, the crack mitigating layer 130 may include an organosilicate or organosilicon material, which can be deposited by atmospheric plasma chemical vapor deposition (AP-CVD), plasma-enhanced chemical vapor deposition (PECVD), low pressure chemical vapor deposition (LPCVD) or spin-on-glass (SOG) processing techniques. In certain aspects, the organosilicate material or organosilicon material is derived from a methylated silica. In some aspects, the organosilicate materials are characterized by a siloxane network with an average silicon connectivity of less than four where each silicon atom on average has some non-zero probability of being directly bonded with up to three organic groups. Typically, such materials are formed by a reaction of mono-, di- or tri-functional organosilicon compounds, optionally with other additions such as silicon precursors and oxidizers. In some aspects, these organosilicate or organosilicon materials are derived from any one of the following organometal precursors: hexamethyldisiloxane (HMDSO), hexamethyldislazane (HMDSN), tetraethylorthosilicate (TEOS), tetramethyldisoloxane (TMDSO), and tetrahethylsilane (TMS). Another aspect involves the development of an organosilicate or organosilicon material for use as the crack mitigating layer 130 using an organoaluminum precursor. In addition, the properties of the crack mitigating layer 130 such as elastic modulus, porosity and surface roughness can be tuned by adjusting one or more of the following parameters depending when a plasma-enhanced chemical vapor deposition technique is employed to develop the layer 130: plasma source frequency and power, working and carry gas flow rate, precursor flow rate, precursor species, the distance between the plasma source and substrate, etc. For PECVD and LPCVD processes, the foregoing parameters can be adjusted to tune the properties of the crack mitigating layer 130 along with chamber pressure, vacuum levels, etc., giving these process methods some additional flexibility.

The organic substitution in these materials employed in the composition for the crack mitigating layer 130 has several advantages of interest. For example, the organic group can lower the surface energy of the silicate with increasing organic substitution from a value near glass (i.e., ˜75 mJ/m² as measured by contact angle with deionized water, hexadecane, and diiodomethane and calculated by the Wu equation) to a value near 35 mJ/m², a value more typical of polymeric materials. Another advantage of the organic substitution is that it can lower the elastic modulus of the material by decreasing its network density, decreasing the polarity of the Si—O—Si bonds, and increasing molar free volume. A further advantage of organic substitution is that it raises the refractive index of the silicate with increasing organic fractions.

In certain other embodiments, the crack mitigating layer 130 is characterized by an elastic modulus of 20 GPa or less, 19 GPa or less, 18 GPa or less, 17 GPa or less, 16 GPa or less, 15 GPa or less, 14 GPa or less, 13 GPa or less, 12 GPa or less, 11 GPa or less, 10 GPa or less, 9 GPa or less, 8 GPa or less, 7 GPa or less, 6 GPa or less, or, more preferably, 5 GPa or less. In some aspects, the crack mitigating layer 130 is characterized by an elastic modulus between about 20 GPa and about 0.1 GPa.

In one or more embodiments, the crack mitigating layer 130 may include low-porosity, oxide structures that include one or more of HfO₂, SiO₂, SiO, SiOₓ, Al₂O₃; TiO₂, ZrO₂, Nb₂O₅, Ta₂O₅, GeO₂ and similar material(s) known in the art. In some cases, the crack mitigating layer 130 can include an inorganic material with low porosity alone or in combination with one or more of the foregoing oxide structures. For example, the inorganic material can include a metal fluoride (e.g., CaF₂, BaF₂, AlF₃, MgF₂, SrF₂, LaF₃ and lanthanide series trifluorides). In some embodiments, the crack mitigating layer 130 can include two or more metal fluorides. The porosity level in the crack mitigating layer 130 when it comprises oxide and/or fluoride structures should be at 20% or less, 19% or less, 18% or less, 17% or less, 16% or less, 15% or less, 14% or less, 13% or less, 12% or less, 11% or less, 10% or less, 9% or less, 8% or less, 7% or less, 6% or less, 5% or less, 4% or less, 3% or less, 2% or less, 1% or less. Unless otherwise noted, the porosity in the crack mitigating layer 130 can be measured in situ during deposition by methods known in the art. In addition, the porosity in a crack mitigating layer 130 within an article 100 containing a film 110 and a substrate 120 can also be measured. For example, the porosity within the layer 130 can be measured and calculated using Rutherford backscattering (“RBS”) and focused ion beam (“FIB”) techniques to ascertain the area density and the thickness of the layer, respectively.

In one implementation, the crack mitigating layer 130 can comprise a highly dense BaF₂ film with a thickness of ˜300 nm having a porosity of about 4%. In another implementation, the crack mitigating layer 130 can comprise a low porosity BaF₂ film with a thickness of ˜300 nm having a porosity of about 19% and a HfO₂ film with a thickness of 100 nm.

Metal fluorides employed in the crack mitigating layer 130 can be deposited in the form of dense crystalline, polycrystalline, semi-amorphous or amorphous films. Further, these films can be deposited as discrete films on the glass substrate 120 by a variety of methods including but not limited to various vacuum and other deposition techniques, e.g., e-beam evaporation, physical vapor deposition, ion-assisted deposition, sputtering, atomic layer deposition (ALD), etc. In some implementations, a dense, amorphous metal fluoride film employed for the crack mitigating layer 130 can comprise material systems that include barium, titanium, zirconium and hafnium fluorides such as: BaF₂—TiF₄, BaF₂—HfF₄. Advantageously, the discrete metal fluoride films, and other inorganic materials, employed in crack mitigating layer 130 can be deposited as discrete films in situ with the subsequent deposition of film 110 using such vacuum deposition techniques. Cleanliness can be maintained during such multiple-film deposition sequences. Further, manufacturing time can be reduced by the deposition of multiple films on the glass substrate 120 in a single vacuum chamber.

In certain aspects, the inorganic material contained in the crack mitigating layer 130 can also include a reaction product derived at least in part from the glass substrate 120. In some of these embodiments, the crack mitigating layer 130 can be developed through the selective etching of certain glass constituents in the surface of the glass substrate 120 (e.g., at the interface 150). In some cases, the deposition and/or etching is performed using a low pressure plasma treatment (e.g., about 50 mTorr).

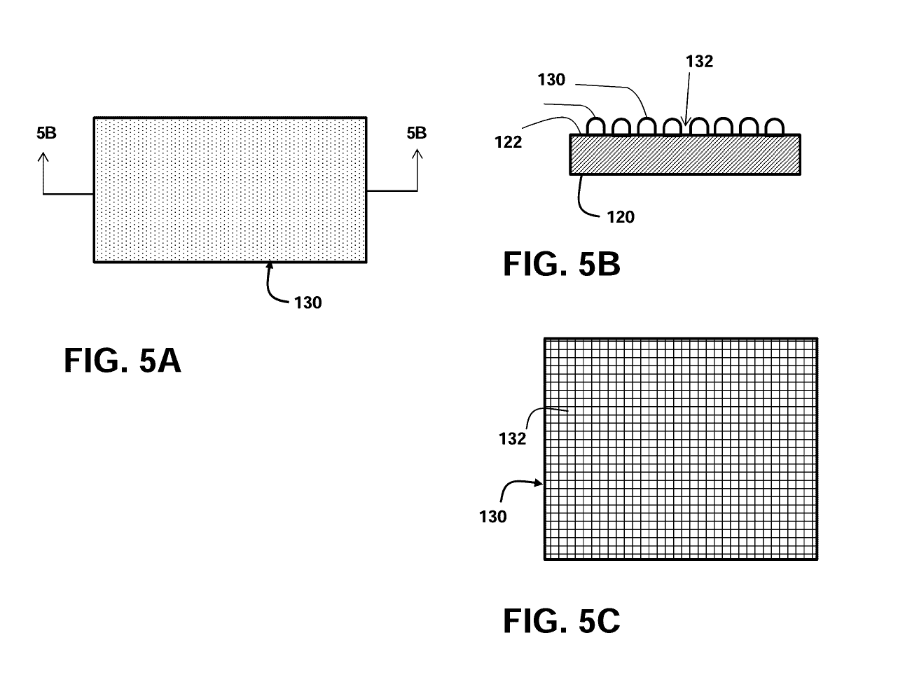

In one or more embodiments, the crack mitigating layer 130 of the laminate articles 100, 100a may be a continuous layer or a discontinuous layer. Where the crack mitigating layer is a discontinuous layer, the first opposing surface 122 on which the crack mitigating layer 130 is disposed may include exposed areas 132 (or areas that do not include the crack mitigating layer 130) and areas that include the crack mitigating layer 130, as shown in FIGS. 5A-5C. The pattern of the crack mitigating layer 130 may include discrete islands of the material surrounded by exposed areas 132 (or areas that do not include the crack mitigating layer 130) as shown in FIG. 5B. Alternatively, the crack mitigating layer 130 may form a continuous matrix of material with exposed areas 132 (or areas that do not include the crack mitigating layer 130) surrounded by the crack mitigating layer 130 as shown in FIG. 5C. The crack mitigating layer 130 may cover about 50%, about 60%, about 70%, about 80%, about 90% or about 100% of the area of the first opposing surface 122. The thickness of the crack mitigating layer 130 may be uniform along substantially all of the areas of the first opposing surface on which it is disposed. In one or more alternative embodiments, the thickness of the crack mitigating layer 130 may vary to provide areas of less thickness and areas of greater thickness. The variation in thickness may be present where the crack mitigating layer is continuous or discontinuous.

The crack mitigating layer 130 may be disposed between the film 110 and the glass substrate 120 (i.e., as employed in laminate article 100), or disposed alone on the substrate 120 (i.e., as employed in laminate article 100a) by a variety of methods. The crack mitigating layer 130 can be disposed using vacuum deposition techniques, for example, chemical vapor deposition (e.g., plasma enhanced chemical vapor deposition, atmospheric pressure chemical vapor deposition, or plasma-enhanced atmospheric chemical vapor deposition), physical vapor deposition (e.g., reactive or nonreactive sputtering, thermal evaporation, e-beam evaporation, or laser ablation), thermal, resistive, or e-beam evaporation and/or atomic layer deposition. The crack mitigating layer 130 of one or more embodiments may exhibit higher temperature tolerance, robustness to UV ozone or plasma treatments, UV transparency, robustness to environmental aging, low outgassing in vacuum, and the like. In instances where the film is also formed by vacuum deposition, both the crack mitigating layer and the film can be formed in the same or similar vacuum deposition chamber or using the same or similar coating equipment.

The crack mitigating layer 130 may also be disposed using liquid-based deposition techniques, for example sol-gel coating or polymer coating methods, for example spin, spray, slot draw, slide, wire-wound rod, blade/knife, air knife, curtain, roller, gravure coating among others and other methods known in the art.

The crack mitigating layer 130 may be substantially optically transparent and free of light scattering, for example having an optical transmission haze of 10% of less, 9% or less, 8% or less, 7% or less, 6% or less, 5% or less, 4% or less, 3% or less, 2% or less, 1% or less and all ranges and sub-ranges therebetween. The transmission haze of the layer may be controlled by controlling the average sizes of pores within the crack mitigating layer 130, as defined herein. Exemplary average pore sizes in the layer may include 200 nm or less, 100 nm or less, 90 nm or less, 80 nm or less, 70 nm or less, 60 nm or less, 50 nm or less, 40 nm or less, 30 nm or less, 20 nm or less, 10 nm or less, 5 nm or less and all ranges and sub-ranges therebetween. These pore sizes can be estimated from light scattering measurements, or directly analyzed using transmission electron microscopy (TEM) and other known methods.

Porosity and mechanical properties of the crack mitigating layer 130 can be controlled using careful control of deposition methods such as a slight overpressure of gas in the vacuum chamber, low temperature deposition, deposition rate control, and plasma and/or ion-beam energy modification. Although vapor deposition methods are commonly used, other known methods can be used to provide a crack mitigating layer with the desired porosity and/or mechanical properties. For example, the crack mitigating layer including a nanoporous layer can also be formed by wet-chemistry or sol-gel methods, such as spin coating, dip coating, slot/slit coating, roller coating, gravure coating, and spray coating.

For certain applications, porosity can be intentionally introduced into the crack mitigating layer 130 by use of a pore former (such as a block copolymer pore former) which is later dissolved or thermally decomposed, phase separation methods, or the casting of a particulate or nanoparticulate layer where interstices between particles remain partially void. In certain aspects of the disclosure, the crack mitigating layer 130 can be prepared with nano-porosity by combined vapor deposition and decomposition methods. These methods include the deposition of a matrix and inert poromers or porogens. The poromers or porogens are then removed from the layer 130 in a subsequent decomposition step to effect the desired nano-porosity. Accordingly, the inert porogens or poromers are appropriately sized, sieved or otherwise processed with regard to their final dimensions and density within the matrix in view of desired nanoporosity in the final, as-processed layer 130.

In some embodiments, the crack mitigating layer 130 may exhibit a similar refractive index to either the glass substrate 120 and/or film 110 and/or additional layers (as described herein), to minimize optical interference effects. Accordingly, the crack mitigating layer 130 can exhibit a refractive index that is somewhat above, equal to or somewhat below the refractive indices of the substrate 120 and/or the film 110. Additionally or alternatively, the crack mitigating layer 130 may exhibit a refractive index that is tuned to achieve anti-reflective interference effects. The refractive index of the crack mitigating layer 130 can be engineered somewhat by controlling the porosity and/or nano-porosity of the layer. For example, in some cases it may be desirable to choose a material with a relatively high refractive index, which when made into a crack mitigating layer with a targeted porosity level can exhibit an intermediate refractive index in the range from about 1.4 to about 1.8 or a refractive index that approximates or is slightly higher than the refractive index of the glass substrate (e.g., in the range from about 1.45 to about 1.6). The refractive index of the crack mitigating layer 130 can be related to the porosity level using “effective index” models that are known in the art.

The thickness (which includes an average thickness where the thickness of the crack mitigating layer varies) of the crack mitigating layer 130 employed in laminate articles 100, 100a may be in the range of about 0.001 μm to about 10 μm (1 nm to 10,000 nm) or in the range from about 0.005 μm to about 0.5 μm (5 nm to about 500 nm), from about 0.01 μm to about 0.5 μm (10 nm to about 500 nm), from about 0.02 μm to about 0.2 μm (20 nm to about 200 nm); however in some cases the film can be much thinner, for example, the crack mitigating layer 130 may be a single-molecule “monolayer” having a thickness of about 0.1 nm to about 1 nm. In one or more embodiments, the thickness of the crack mitigating layer 130 is in the range from about 0.02 μm to about 10 μm, from about 0.03 μm to about 10 μm, from about 0.04 μm to about 10 μm, from about 0.05 μm to about 10 μm, from about 0.06 μm to about 10 μm, from about 0.07 μm to about 10 μm, from about 0.08 μm to about 10 μm, from about 0.09 μm to about 10 μm, from about 0.1 μm to about 10 μm, from about 0.01 μm to about 9 μm, from about 0.01 μm to about 8 μm, from about 0.01 μm to about 7 μm, from about 0.01 μm to about 6 μm, from about 0.01 μm to about 5 μm, from about 0.01 μm to about 4 μm, from about 0.01 μm to about 3 μm, from about 0.01 μm to about 2 μm, from about 0.01 μm to about 1 micron, from about 0.02 μm to about 1 micron, from about 0.03 to about 1 μm, from about 0.04 μm to about 0.5 μm, from about 0.05 μm to about 0.25 μm or from about 0.05 μm to about 0.15 μm. In one or more specific embodiments, the thickness of the crack mitigating layer may be about 30 nm or less, about 20 nm or less, about 10 nm or less, about 5 nm or less, about 4 nm or less, about 3 nm or less, about 2 nm or less or about 1 nm or less.

In one or more embodiments, thicknesses of the glass substrate 120, film 110 and/or crack mitigating layer 130 may be specified in relation to one another. For example, the crack mitigating layer 130 may have a thickness that is less than or equal to about 10 times the thickness of the film. In another example, where a film 110 has a thickness of about 85 nm, the crack mitigating layer 130 may have a thickness of about 850 nm or less. In yet another example, the thickness of the crack mitigating layer 130 may be in the range from about 35 nm to about 80 nm and the film 110 may have a thickness in the range from about 30 nm to about 300 nm. In one variant, the crack mitigating layer 130 may have a thickness that is less than or equal to about 9 times, 8 times, 7 times, 6 times, 5 times, 4 times, 3 times or two times the thickness of the film 110. In another variant, the thickness of the film 110 and the thickness of the crack mitigating layer 130 are each less than about 10 μm, less than about 5 μm, less than about 2 μm, less than about 1 μm, less than about 0.5 μm, or less than about 0.2 μm. The ratio of the crack mitigating layer 130 thickness to the film 110 thickness may be, in some embodiments, in the range from about 1:1 to about 1:8, in the range from about 1:2 to about 1:6, in the range from about 1:3 to about 1:5, or in the range from about 1:3 to about 1:4. In another variant, the thickness of the crack mitigating layer 130 is less than about 0.1 μm and the thickness of the film 110 is greater than the crack mitigating layer.

One or more embodiments of the laminate articles include a crack mitigating layer 130 comprising an organosilicate material, a metal fluoride, a metal oxide, or combinations thereof. In such embodiments, when the crack mitigating layer 130 is utilized, the film 110 maintains functional properties (e.g., optical properties, electrical properties and mechanical properties) and the article 100 retains its average flexural strength. In such embodiments, the film 110 may include one or more transparent conductive oxide layers, such as indium-tin-oxide layers or scratch resistant layer, such as AlOxNy, AlN and combinations thereof. In addition, the glass substrate 120 may be strengthened, or more specifically, chemically strengthened.

Additionally or alternatively, the film 110 including one or more of an indium-tin-oxide layer, a scratch-resistant layer (e.g., AlOxNy, AlN and combinations thereof), an easy-to-clean layer, an anti-reflective layer, an anti-fingerprint layer and the like, and the crack mitigating layer 130 comprising an organosilicate material, a metal fluoride, a metal oxide, or combinations thereof, form a stack, wherein the stack has an overall low optical reflectance. For example, the overall (or total) reflectance of such a stack may be 15% or less, 10% or less, 8% or less, 7% or less, 6.5% or less, 6% or less, 5.5% or less across a visible wavelength range from 450-650 nm, 420-680 nm, or even 400-700 nm. The reflectance numbers above may be present in some embodiments including the reflectance from one bare (or uncoated) glass interface, which is approximately 4% reflectance from the uncoated glass interface alone, or may be characterized as the reflectance for a first major surface of a glass substrate and the films and layers (and associated interfaces) disposed on the first major surface (excluding the 4% reflectance from an uncoated second major surface of the glass substrate). The reflectance from the film stack structure and film-glass coated interfaces alone (subtracting out the reflectance of the uncoated glass interface) may be less than about 5%, 4%, 3%, 2%, or even less than about 1.5% across a visible wavelength range from 450-650 nm, 420-680 nm, or even 400-700 nm, in some cases when one or more major surfaces of the glass substrate is covered by a typical encapsulant (i.e. an additional film or layer) having an encapsulant refractive index of about 1.45-1.65. In addition, the stack structure may exhibit a high optical transmittance, which indicates both low reflectance and low absorptance, according to the general relationship: Transmittance=100%−Reflectance−Absorptance. The transmittance values for the stack structure (when neglecting reflectance and absorptance associated with the glass substrate or encapsulant layers alone) may be greater than about 75%, 80%, 85%, 90%, 95%, or even 98% across a visible wavelength range from 450-650 nm, 420-680 nm, or even 400-700 nm.

The optical properties of the laminate articles 100, 100a may be adjusted by varying one or more of the properties of the film 110, crack mitigating layer 130 and/or the glass substrate 120. For example, the articles 100, 100a may exhibit a total reflectance of 15% or less, 10% or less, 8% or less, 7% or less, 6.9% or less, 6.8% or less, 6.7% or less, 6.6% or less, 6.5% or less, 6.4% or less, 6.3% or less, 6.2% or less, 6.1% or less and/or 6% or less, over the visible wavelength range from about 400 nm to about 700 nm. Ranges may further vary as specified hereinabove, and ranges for the film stack/coated glass interfaces alone are listed hereinabove. In more specific embodiments, the articles 100, 100a described herein, may exhibit a lower average reflectance and greater average flexural strength than articles without a crack mitigating layer 130. In one or more alternative embodiments, at least two of optical properties, electrical properties or mechanical properties of the article 100 may be adjusted by varying the thickness(es) of the glass substrate 120, film 110 and/or the crack mitigating layer 130. Additionally or alternatively, the average flexural strength of the articles 100, 100a may be adjusted or improved by modifying the thickness(es) of the glass substrate 120, film 110 and/or the crack mitigating layer 130.

The articles 100, 100a may include one or more additional films disposed on the glass substrate 120. In one or more embodiments of the article 100, the one or more additional films may be disposed on the film 110 or on the opposite major surface from the film. The additional film(s) may be disposed in direct contact with the film 110. In one or more embodiments, the additional film(s) may be positioned between: 1) the glass substrate 120 and the crack mitigating layer 130 (e.g., in laminate articles 100a); or 2) the crack mitigating layer 130 and the film 110 (e.g., in laminate articles 100). In one or more embodiments, both the crack mitigating layer 130 and the film 110 may be positioned between the glass substrate 120 and the additional film(s). The additional film(s) may include a protective layer, an adhesive layer, a planarizing layer, an anti-splintering layer, an optical bonding layer, a display layer, a polarizing layer, a light-absorbing layer, reflection-modifying interference layers, scratch-resistant layers, barrier layers, passivation layers, hermetic layers, diffusion-blocking layers and combinations thereof, and other layers known in the art to perform these or related functions. Examples of suitable protective or barrier layers include layers containing SiOₓ, SiN_{y}, SiOₓN_{y}, other similar materials and combinations thereof. Such layers can also be modified to match or complement the optical properties of the film 110, the crack mitigating layer 130 and/or the glass substrate 120. For example, the protective layer may be selected to have a similar refractive index as the crack mitigating layer 130, the film 110, or the glass substrate 120. It will be apparent to those of ordinary skill in the art that multiple additional film(s) with varying refractive indices and/or thicknesses can be inserted for various reasons. The refractive indices, thicknesses and other properties of the additional films (as well as the crack mitigating layer 130 and the film 110) may be further modified and optimized, without departing from the spirit of the disclosure. In other cases, for example, alternate film designs can be employed where the crack mitigating layer 130 may have a higher refractive index than the film.

In one or more embodiments, the articles 100, 100a described may be used in information display devices and/or touch-sensing devices. In one or more alternative embodiments, the articles 100, 100a may be part of a laminate structure, for example as a glass-polymer-glass laminated safety glass to be used in automotive or aircraft windows. An exemplary polymer material used as an interlayer in these laminates is PVB (polyvinyl butyral), and there are many other interlayer materials known in the art that can be used. In addition, there are various options for the structure of the laminated glass, which are not particularly limited. The articles 100, 100a may be curved or shaped in the final application, for example as in an automotive windshield, sunroof, or side window. The thickness of the articles 100, 100a can vary, for either design or mechanical reasons; for example, the articles 100, 100a can be thicker at the edges than at the center of the article. The articles 100, 100a may be acid-polished or otherwise treated to remove or reduce the effect of surface flaws.

A second aspect of the present disclosure pertains to cover glass applications that utilize the articles 100 described herein. In one or more embodiments, the cover glass may include a laminated article with a glass substrate 120 (which may be strengthened or not strengthened), a scratch-resistant film (e.g., film 110) including hard material(s) such as AlOₓN_{y}, AlN, SiOₓN_{y}, SiAlᵥOₓN_{y}, Si₃N₄ and combinations thereof, and the crack mitigating layer 130. The laminated article may include one or more additional film(s) for reducing the reflection and/or providing an easy to clean or anti-fingerprint surface on the laminated article.

Another aspect of the present disclosure pertains to touch-sensing devices including the articles described herein. In one or more embodiments, the touch sensor device may include a glass substrate 120 (which may be strengthened or not strengthened), a film 110 comprising a transparent conductive oxide and a crack mitigating layer 130. The transparent conductive oxide may include indium-tin-oxide, aluminum-zinc-oxide, fluorinated tin oxide, or others known in the art. In one or more embodiments, the film 110 is discontinuously disposed on the glass substrate 120. In other words, the film 110 may be disposed on discrete regions of the glass substrate 120. The discrete regions with the film form patterned or coated regions (not shown), while the discrete regions without the film form unpatterned or uncoated regions (not shown). In one or more embodiments, the patterned or coated regions and unpatterned or uncoated regions are formed by disposing the film 110 continuously on a surface of the glass substrate 120 and then selectively etching away the film 110 in the discrete regions so that there is no film 110 in those discrete regions. The film 110 may be etched away using an etchant such as HCl or FeCl₃ in aqueous solutions, such as the commercially available TE-100 etchant from Transene Co. In one or more embodiments, the crack mitigating layer 130 is not significantly degraded or removed by the etchant. Alternatively, the film 110 may be selectively deposited onto discrete regions of a surface of the glass substrate 120 to form the patterned or coated regions and unpatterned or uncoated regions.

In one or more embodiments, the uncoated regions have a total reflectance that is similar to the total reflectance of the coated regions. In one or more specific embodiments, the unpatterned or uncoated regions have a total reflectance that differs from the total reflectance of the patterned or coated regions by about 5% or less, 4.5% or less, 4% or less, 3.5% or less, 3% or less, 2.5% or less, 2.0% or less, 1.5% or less or even 1% or less across a visible wavelength in the range from about 450 nm to about 650 nm, from about 420 nm to about 680 nm or even from about 400 nm to about 700 nm.

In accordance with another aspect of the present disclosure, articles 100 including both a crack mitigating layer 130 and a film 110, which may include indium-tin-oxide or other transparent conductive oxides, exhibit resistivity that is acceptable for use of such articles in touch sensing devices. In one or more embodiments, the films 110, when present in the articles disclosed herein, exhibit a sheet resistance of about 100 ohm/square or less, 80 ohm/square or less, 50 ohm/square or less, or even 30 ohm/square or less. In such embodiments, the film may have a thickness of about 200 nm or less, 150 nm or less, 100 nm or less, 80 nm or less, 50 nm or less or even 35 nm or less. In one or more specific embodiments, such films, when present in the article 100, exhibit a resistivity of 10×10⁻⁴ ohm-cm or less, 8×10⁻⁴ ohm-cm or less, 5×10⁻⁴ ohm-cm or less, or even 3×10⁻⁴ ohm-cm or less. Thus, the films 110, when present in the articles 100 disclosed herein can favorably maintain the electrical and optical performance expected of transparent conductive oxide films and other such films used in touch sensor applications, including projected capacitive touch sensor devices.

The disclosure herein can also be applied to articles 100, 100a which are not interactive or for display; for example, such articles may be used in a case in which a device has a glass front side that is used for display and can be interactive, and a back side that might be termed “decorative” in a very broad sense, meaning that backside can be “painted” in some color, have art work or information about the manufacturer, model and serial number, texturing or other features.

With regard to the optical properties of the laminate articles 100 (see FIG. 1), the film 110 can comprise a scratch-resistant material, such as AlN, Si₃N₄, AlOₓN_{y}, and SiOₓN_{y}, which possesses a relatively high refractive index in the range from about 1.7 to about 2.1. The glass substrates 120 employed in laminate articles 100 and 100a (see FIG. 1A) typically have refractive indices in the range from about 1.45 to about 1.65. Further, the crack mitigating layer 130 employed in articles 100 and 100a typically has a refractive index somewhere near or between the refractive index ranges common to the substrate 120 and the film 110 (when present). The differences in these refractive index values (e.g., between the substrate 120 and the crack mitigating layer 130) can contribute to undesirable optical interference effects. In particular, optical interference at the interfaces 150 and/or 160 (see FIGS. 1 and 1A) can lead to spectral reflectance oscillations that create apparent color in observed in the articles 100 and 100a. The color shifts in reflection with viewing angle due to a shift in the spectral reference oscillations with incident illumination angle. Ultimately, the observed color and color shifts with incident illumination angle are often distracting or objectionable to device users, particularly under illumination with sharp spectral features such as fluorescent lighting and some LED lighting.

According to aspects of this disclosure, observed color and color shifts in the articles 100 and 100a can be reduced by minimizing reflectance at one or both of the interfaces 150 and 160, thus reducing reflectance oscillations and reflected color shifts for the entire article. In some aspects, the density, thickness, composition and/or porosity of the crack mitigating layer 130 can be tailored to minimize such reflectance at the interfaces 150 and 160. For example, configuring the layer 130 according to the foregoing aspects can reduce the amplitudes and/or oscillations of the reflectance across the visible spectrum.

As used herein, the term “amplitude” includes the peak-to-valley change in reflectance or transmittance. As also used herein, the term “transmittance” is defined as the percentage of incident optical power within a given wavelength range transmitted through the articles 100 and 100a. The term “average transmittance” refers to the spectral average of the light transmission multiplied by the luminous efficiency function, as described by CIE standard observer. The term “reflectance” is similarly defined as the percentage of incident optical power within a given wavelength range that is reflected from the articles 100 and 100a. In general, transmittance and reflectance are measured using a specific linewidth. Furthermore, the phrase “average amplitude” includes the peak-to-valley change in reflectance or transmittance averaged over every possible 100 nm wavelength range within the optical wavelength regime. As used herein, the “optical wavelength regime” includes the range from about 420 nm to about 700 nm.

According to one or more embodiments, the laminated articles 100 and 100a exhibit an average transmittance of 85% or greater over the visible spectrum. In some embodiments, the laminated articles 100 and 100a can exhibit an average transmittance of 80% or greater, 82% or greater, 85% or greater, 90% or greater, 91% or greater, 92% or greater, 93% or greater, 94% or greater, or 95% or greater.

In some aspects, the articles 100 and 100a exhibit an average total reflectance of 20% or less over the visible spectrum. Certain embodiments of the articles 100, 100a, for example, exhibit a total reflectance of 20% or less, 15% or less, 10% or less, 9% or less, 8% or less, 7% or less, 6% or less, or 5% or less.

In accordance with one or more embodiments, the articles 100 and 100a have a total reflectivity that is the same or less than the total reflectivity of the glass substrate 120. In one or more embodiments, the articles 100 and 100a exhibit a relatively flat transmittance spectrum, reflectance spectrum or transmittance and reflectance spectrum over the optical wavelength regime. In some embodiments, the relatively flat transmittance and/or reflectance spectrum includes an average oscillation amplitude of about 5 percentage points or less along the entire optical wavelength regime or wavelength range segments in the optical wavelength regime. Wavelength range segments may be about 50 nm, about 100 nm, about 200 nm or about 300 nm. In some embodiments, the average oscillation amplitude may be about 4.5 percentage points or less, about 4 percentage points or less, about 3.5 percentage points or less, about 3 percentage points or less, about 2.5 percentage points or less, about 2 percentage points or less, about 1.75 percentage points or less, about 1.5 percentage points or less, about 1.25 percentage points or less, about 1 percentage point or less, about 0.75 percentage points or less, about 0.5 percentage points of less, about 0.25 percentage points or less, or about 0 percentage points, and all ranges and sub-ranges therebetween. In one or more specific embodiments, the articles 100 and 100a exhibit a transmittance over a selected wavelength range segment of about 100 nm or 200 nm over the optical wavelength regime, wherein the oscillations from the spectra have a maximum peak of about 80%, about 82%, about 84%, about 86%, about 87%, about 88%, about 89%, about 90%, about 91%, about 92%, about 93%, about 94%, or about 95%, and all ranges and sub-ranges therebetween.

In some embodiments, the relatively flat average transmittance and/or average reflectance includes maximum oscillation amplitude, expressed as a percent of the average transmittance or average reflectance, along a specified wavelength range segment in the optical wavelength regime. The average transmittance or average reflectance of the laminated articles 100 and 100a would also be measured along the same specified wavelength range segment in the optical wavelength regime. The wavelength range segment may be about 50 nm, about 100 nm or about 200 nm. In one or more embodiments, the articles 100 and 100a exhibit an average transmittance and/or average reflectance with an average oscillation amplitude of about 10% or less, about 5% or less, about 4.5% of less, about 4% or less, about 3.5% or less, about 3% or less, about 2.5% or less, about 2% or less, about 1.75% or less, about 1.5% or less, about 1.25% or less, about 1% or less, about 0.75% or less, about 0.5% or less, about 0.25% or less, or about 0.1% or less, and all ranges and sub-ranges therebetween. Such percent-based average oscillation amplitude may be exhibited by the article along wavelength ranges segments of about 50 nm, about 100 nm, about 200 nm or about 300 nm, in the optical wavelength regime. For example, an article according to this disclosure may exhibit an average transmittance of about 85% along the wavelength range from about 500 nm to about 600 nm, which is a wavelength range segment of about 100 nm, within the optical wavelength regime. The article may also exhibit a percent-based oscillation amplitude of about 3% along the same wavelength range (500 nm to about 600 nm), which means that along the wavelength range from 500 nm to 600 nm, the absolute (non-percent-based) oscillation amplitude is about 2.55 percentage points.

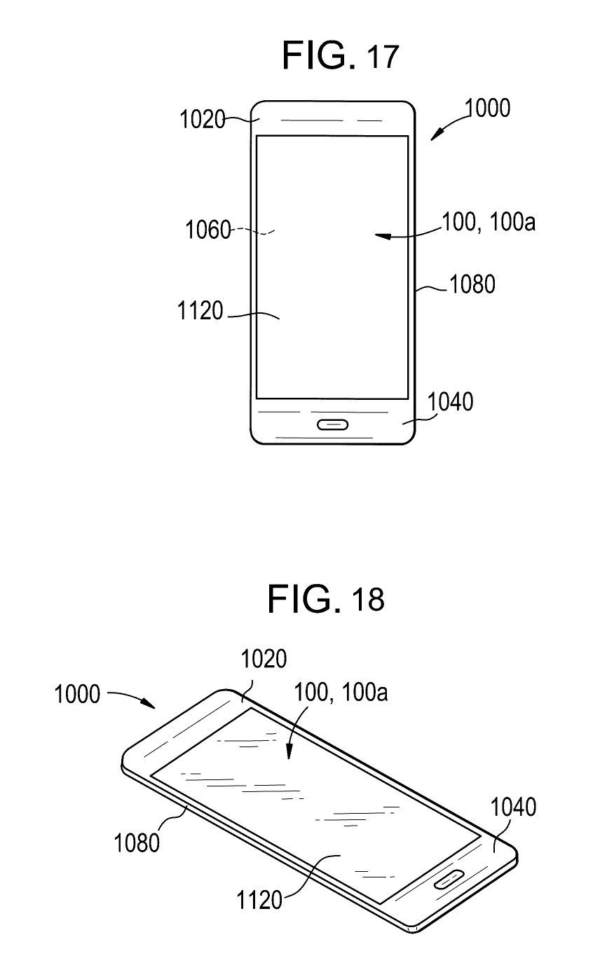

A second aspect of this disclosure pertains to a device incorporating the articles 100, 100a disclosed herein, as shown in FIGS. 17 and 18. The device shown in FIGS. 17-18 is a mobile phone but can include any device or article with a display (e.g., consumer electronics, including mobile phones, tablets, computers, navigation systems, and the like), architectural articles, transportation articles (e.g., automotive, trains, aircraft, sea craft, etc.), appliance articles, or any article that requires some transparency, scratch-resistance, abrasion resistance or a combination thereof. FIG. 17 shows a consumer electronic device 1000 including a housing 1020 having front 1040, back 1060, and side surfaces 1080; electrical components (not shown) that are at least partially inside or entirely within the housing and including at least a controller, a memory, and a display 1120 at or adjacent to the front surface of the housing; and an article 100, 100a at or over the front surface of the housing such that it is over the display. In some embodiments, the housing 1020 may include articles 100, 100a at any one or more of the back 1060, side surfaces 1080 or portions of the front 1040.

Another aspect of the present disclosure pertains to methods of forming articles 100 and 100a. In one or more embodiments, such methods include providing a glass substrate 120, disposing a film 110 on a first major surface of the glass substrate to create an effective interface therebetween and controlling the effective adhesion energy of the effective interface. In certain aspects, such methods include providing a glass substrate 120 and creating an effective interface on the substrate, and controlling the effective adhesion energy of the effective interface. In one or more embodiments, the method includes controlling the effective adhesion energy to less than about 4 J/m². In one or more embodiments, controlling the effective adhesion energy includes disposing a crack mitigating layer 130 on a surface (e.g., one or more of the major surfaces 122, 124 and/or one or more minor surfaces) of the glass substrate 120, before disposing the film (e.g., for articles 100). In other words, controlling the effective adhesion energy includes disposing a crack mitigating layer 130 between the film 110 and the glass substrate 120 for articles 100 and disposing a crack mitigating layer 130 on the substrate 120 for articles 100a.

In the method of forming articles 100 and 100a, the crack mitigating layer 130 can include fluorine and, in some cases, may further include a metal. According to some embodiments, the crack mitigating layer 130 includes a metal fluoride. In addition, the metal fluoride can be deposited on the glass substrate 120 by physical vapor and other deposition techniques that include, but are not limited to, evaporation, e-beam evaporation, ion-assisted deposition, sputtering and atomic layer deposition (ALD) techniques. When the crack mitigating layer 130 incorporates two or more metal fluorides, some of the foregoing techniques can be employed to co-deposit such materials in a single film structure as understood by those with skill in the field. In other implementations, the crack mitigating layer can include metal oxides alone or in combination with the foregoing metal fluoride(s). The metal oxide layers can be developed through various thermal processes, including deposition of the metal via any of the foregoing deposition techniques followed by thermal treatment in an oxidative environment.

According to some implementations, the method of forming articles 100 and 100a employs a crack mitigating layer 130 that includes an organosilicate material, e.g., methylated silica. As such, these methods for forming articles 100, 100a can employ steps for depositing the crack mitigating layer that include any one of the following deposition techniques: atmospheric plasma chemical vapor deposition (AP-CVD), plasma-enhanced chemical vapor deposition (PECVD), or spin-on-glass (SOG) processing techniques. In some aspects, the organosilicate materials are characterized by a siloxane network with an average silicon connectivity of less than four where each silicon atom on average has some non-zero probability of being directly bonded with up to three organic groups. Typically, such materials are formed by a reaction of mono-, di- or tri-functional organosilicon compounds, optionally with other additions such as silicon precursors and oxidizers.

In one or more embodiments, the method includes disposing the film 110 and/or the crack mitigating layer 130 via a vacuum deposition process. In particular embodiments, such vacuum deposition processes may utilize temperatures of at least about 25° C., 50° C., 75° C., 100° C., 200° C., 300° C., 400° C. and all ranges and sub-ranges therebetween. In some embodiments, the crack mitigating layer 130 may be formed by a wet process.

In one or more specific embodiments, the method includes controlling the thickness(es) of the crack mitigating layer 130 and/or the film 110. Controlling the thickness(es) of the crack mitigating layer and/or films disclosed herein may be performed by controlling one or more processes for forming the crack mitigating layer and/or films so that the crack mitigating layer and/or films are applied having a desired or defined thickness. In an even more specific embodiment, the method includes controlling the thickness(es) of the crack mitigating layer 130 and/or the film 110 to maintain (or enhance, in some cases) the average flexural strength of the glass substrate 120, the functional properties of the glass substrate 120 and/or the functional properties of the film 110.

In one or more alternative embodiments, the method includes controlling the continuity of the crack mitigating layer 130 and/or the film. Controlling the continuity of the crack mitigating layer 130 may include forming a continuous crack mitigating layer and removing a selected portion(s) of the crack mitigating layer to create a discontinuous crack mitigating layer. In other embodiments, controlling the continuity of the crack mitigating layer may include selectively forming the crack mitigating layer to form a discontinuous crack mitigating layer. Such embodiments may use a mask, an etchant and combinations thereof to control the continuity of the crack mitigating layer.

In one or more alternative embodiments, the method includes controlling the surface energy of the crack mitigating layer 130 when it is disposed on the glass substrate 120 (with regard to methods of forming laminate articles 100, 100a), but before deposition of the film 110 (with particular regard to articles 100a). Controlling the surface energy of the crack mitigating layer at this intermediate stage of fabrication may be useful for establishing a repeatable fabrication process. In one or more embodiments, the method includes controlling the surface energy of the crack mitigating layer 130 (as measured when the crack mitigating layer 130 is uncovered and exposed to air) to less than about 70 mJ/m² or less, 60 mJ/m² or less, 50 mJ/m² or less, 40 mJ/m² or less, 30 mJ/m² or less, 20 mJ/m² or less, but in some cases, greater than about 15 mJ/m². In one or more embodiments, the foregoing surface energy values and ranges include both polar and dispersion components and may be measured by fitting a known theoretical model developed by S. Wu (1971) to three contact angles of three test liquids; water, diiodomethane and hexadecane. (See S. Wu, J. Polym. Sci., Part C, vol. 34, pp. 19-30, 1971).

In one or more embodiments, the method may include creating a controlled amount of porosity in the crack mitigating layer 130. The method may optionally include controlling the porosity of the crack mitigating layer as otherwise described herein. The method may further include controlling the intrinsic film stresses of the crack mitigating layer and/or the film through control of deposition and fabrication processes of the crack mitigating layer.

The method may include disposing an additional film, as described herein, on the glass substrate 120. In one or more embodiments, the method may include disposing the additional film on the glass substrate such that the additional film is disposed between the glass substrate 120 and the crack mitigating layer 130, between the crack mitigating layer 130 and the film 110 or, such that the film 110 is between the crack mitigating layer 130 and the additional film. Alternatively, the method may include disposing the additional film on the opposite major surface of the glass substrate 120 from the surface on which the film is disposed.

In one or more embodiments, the method includes strengthening the glass substrate 120 before or after disposing the crack mitigating layer 130, film 110 and/or an additional film on the glass substrate. The glass substrate 120 may be strengthened chemically or otherwise. The glass substrate 120 may be strengthened after disposing the crack mitigating layer 130 on the glass substrate 120 but before disposing the film 110 on the glass substrate. The glass substrate 120 may be strengthened after disposing the crack mitigating layer 130 and the film 110 on the glass substrate 120 but before disposing an additional film (if any) on the glass substrate. Where no additional film is utilized, the glass substrate 120 may be strengthened after disposing the crack mitigating layer 130 and the film 110 on the glass substrate.

The following examples represent certain non-limiting embodiments of the disclosure.

### Example 1

### Strength of Laminated Articles Having BaF₂ and BaF₂/HfO₂ Crack Mitigation Layers

Sample laminated articles designated Examples 1A-1D (“Exs. 1A-1D”) were formed by providing glass substrates according to the following composition: SiO₂ of about 65 mol %, B₂O₃ of about 5 mol %, Al₂O₃ of about 14 mol %, Na₂O of about 14 mol %, and MgO of about 2.5 mol %. The glass substrates had a thickness of 1 mm. The glass substrates were strengthened by ion exchange to provide a surface compressive stress (CS) of about 690 MPa and a compressive depth of layer (DOL) of about 24 μm. The ion-exchange process was carried out by immersing the glass substrate in a molten potassium nitrate (KNO₃) bath that was heated to a temperature in the range from about 350° C. to 450° C. The glass substrates were immersed in the bath for a duration of 3-8 hours to achieve the surface CS and compressive DOL. After completing the ion exchange process, the glass substrates of Examples 1A-1 D were cleaned in a 2% concentration KOH detergent solution, supplied by Semiclean KG, having a temperature of about 50° C.

In Example 1, the Ex. 1A sample represents a control as it only contains a glass substrate. Similarly, the Ex. 1B sample also serves as a control because it contains a SiNₓ scratch-resistant film having a thickness of about 440 nm and lacks a crack mitigation layer. In the Ex. 1B sample, the SiNₓ scratch-resistant film was deposited in a Plasma-Therm Versaline HDPCVD system at 150° C. with a silane precursor gas and nitrogen gas. In the Exs. 1C and 1D samples, glass substrates and scratch-resistant SiNₓ films were employed according to the Exs. 1A and 1B. In addition, Exs. 1C and 1D possess a crack mitigation layer comprising a BaF₂ film having a thickness of about 300 nm. More specifically, the crack mitigation layer employed in the Ex. 1C sample comprised a BaF₂/HfO₂ structure in which the HfO₂ film is about 100 nm in thickness. In Ex. 1C, the BaF₂ film was processed at 50° C. and configured with a porosity of about 19%. With regard to Ex. 1D, the BaF₂ film employed in this sample laminate article was significantly denser than the BaF₂ film employed in Ex. 1C given that it was processed at 200° C. and configured with a porosity of about 4%.

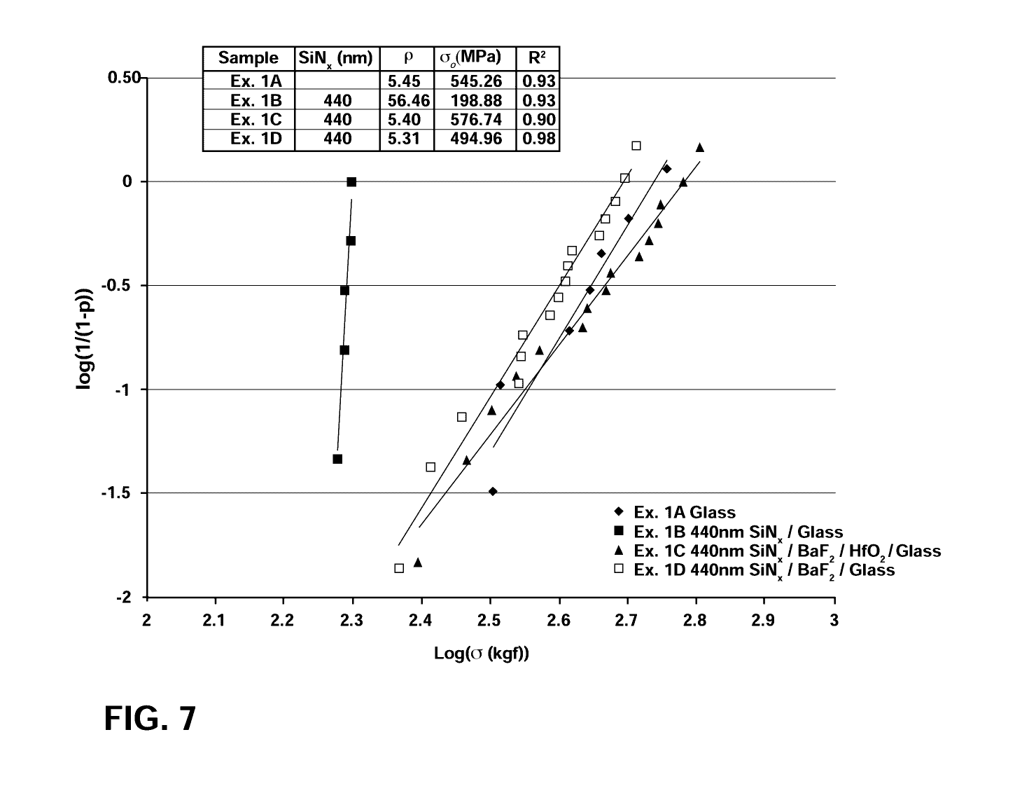

Ring-on-ring (ROR) load to failure testing was used to demonstrate the retention of average flexural strength of Exs. 1A-1D, as shown in FIG. 7. For ROR load-to-failure testing, the side with the film and/or crack mitigating layer was placed in tension. The ROR load-to-failure testing parameters included a contact radius of 1.6 mm, a cross-head speed of 1.2 mm/minute, a load ring diameter of 0.5 inches, and a support ring diameter of 1 inch. Before testing, an adhesive film was placed on both sides of the sample being tested to contain broken glass shards.

As illustrated in FIG. 7, the addition of a crack mitigating layer comprising BaF₂ or BaF₂/HfO₂ (Exs. 1C and 1D, respectively) resulted in laminated articles that retained about the same average flexural strength as glass substrates without a crack mitigating layer or film (Ex. 1A). Moreover, the articles with a crack mitigating layer (Exs. 1C and 1D) exhibited greater average flexural strength than the articles comprising strengthened glass substrates with only a SiNₓ film and no crack mitigating layer (Ex. 1B). In particular, the Ex. 1B samples having a SiNₓ film and no crack mitigation layer exhibited a substantial reduction in the average flexural strength compared to the control samples comprising only a strengthened glass substrate with no additional films or layers (Ex. 1A).

### Example 2

### Optical Properties of Laminated Articles Having a BaF₂ Crack Mitigation Layer and a SiNₓ Scratch-Resistant Film

Laminated article samples designated Examples 2A-2E (“Exs. 2A-2E”) were made in Example 2 by providing 0.7 mm thick ion-exchange strengthened aluminosilicate glass substrates. These substrates possessed the same composition as Example 1. The glass substrates were ion-exchanged in a KNO₃ molten salt bath having a temperature of about 350-450° C. for 3-8 hours. The ion-exchanged glass substrates had a compressive stress of about 687 MPa and an ion-exchange depth of layer of about 24 microns. The glass substrates were then cleaned in a KOH detergent solution (1-4% Semiclean KG), having a temperature of about 50-70° C. with ultrasonic agitation at 40-110 KHz, rinsed in DI water with ultrasonics in the same frequency range, and dried.

In Example 2, the Ex. 2A sample represents a control as it only contains a glass substrate. Similarly, the Ex. 2B sample also serves as a control because it contains an eight layer scratch-resistant (“8L SCR”) film having layer thicknesses as outlined below in Table 1 and lacks a crack mitigation layer. In the Ex. 2B sample, the scratch-resistant film stack was deposited with the same system and parameters as employed for the applicable samples of Example 1. In the Exs. 2C, 2D and 2E samples, glass substrates were employed according to Exs. 2A and 2B. In addition, Exs. 2C, 2D and 2E possess a crack mitigation layer comprising BF₂ having a thickness of about 200 nm. In Exs. 2C and 2D, the BaF₂ portion of the crack mitigating layer structure was processed at 50° C. and configured with a porosity of about 19%. In Ex. 2E, the crack mitigating layer structure was processed at 200° C. and configured with a porosity of about 4%. In addition, Exs. 2D and 2E have an 8L SCR stack as described below in Table 1 deposited over the crack mitigating layer.

TABLE 1
Eight layer scratch-resistant coating design for Exs. 2A-2E

| | | | |
|---|---|---|---|
| Layer | Examples | Material | Thickness |

| | | | | |
|---|---|---|---|---|
| 1 | 2B, 2D, 2E | SiO₂ | 19.2 | nm |
| 2 | 2B, 2D, 2E | SiNₓ | 2000 | nm |
| 3 | 2B, 2D, 2E | SiO₂ | 8.5 | nm |
| 4 | 2B, 2D, 2E | SiNₓ | 38.4 | nm |
| 5 | 2B, 2D, 2E | SiO₂ | 26.4 | nm |
| 6 | 2B, 2D, 2E | SiNₓ | 22.8 | nm |
| 7 | 2B, 2D, 2E | SiO₂ | 44.1 | nm |
| 8 | 2B, 2D, 2E | SiNₓ | 7.7 | nm |
| Crack | 2C, 2D, 2E | BaF₂ | ~200 | nm |
| mitigating layer | | | | |
| Substrate | 2A-2E | Corning ® | ~ 1 | mm |
| | | 5318 Glass | | |

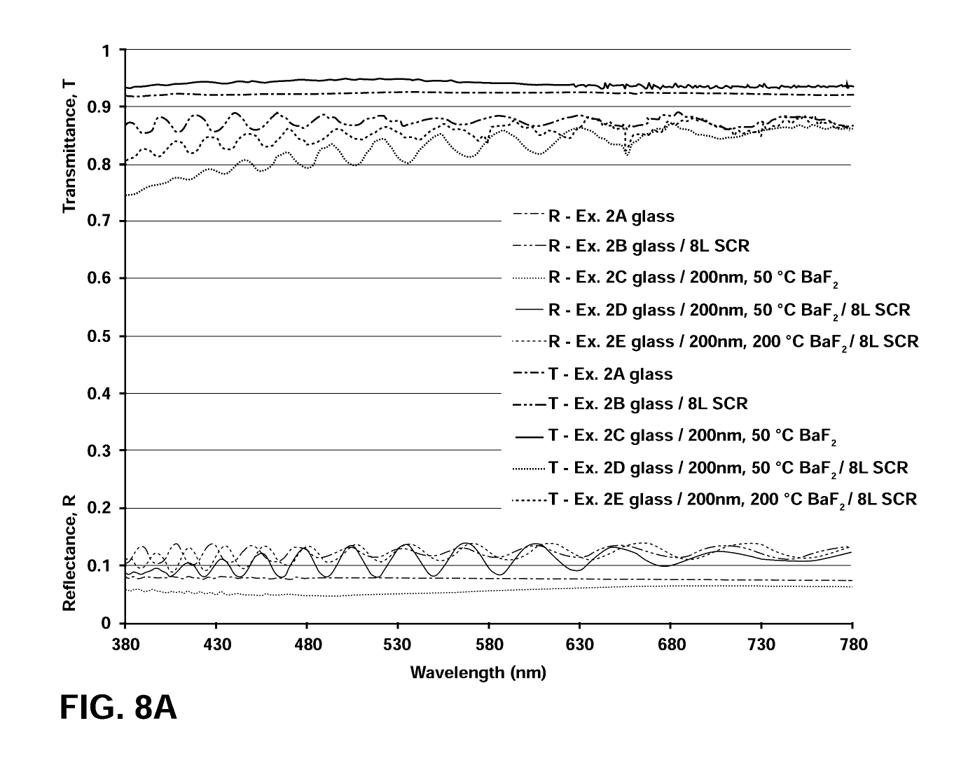

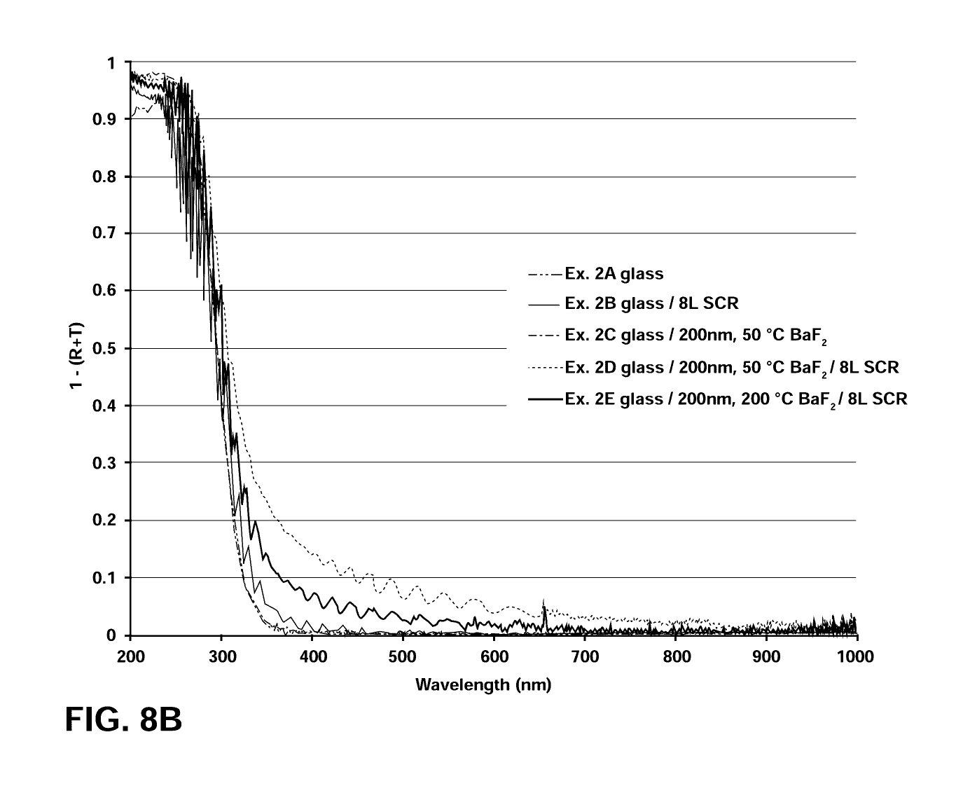

In FIG. 8A, reflectance and transmittance spectra are provided for the laminated articles designated Exs. 2A through 2E. The prefix “R” and “T” in the legend each denote series of data that correspond to reflectance and transmittance data, respectively. More specifically, the oscillations in the reflectance and transmittance spectra in the optical wavelength regime (i.e., between 420 nm and 700 nm) are no greater than about 14%. The laminated article samples designated by Exs. 2A, 2B, 2C, 2D and 2E exhibit R and T oscillations of 3 to 5% or less over the visible wavelength range. Notably, the Ex. 2D sample with a porous BaF₂ crack mitigation layer and an 8L SCR stack exhibited the largest transmittance reduction relative to the bare glass substrate and the substrate with the 8L SCR stack controls (Exs. 2A and 2B). In particular, Ex. 2D exhibited transmittance levels between about 75% and 85% from 380 to 780 nm.

Referring to FIG. 8B, this graph depicts 1−(R+T) as a function of wavelength for Exs. 2A, 2B, 2C, 2D and 2E, where R is reflectance and T is transmittance. That is, the quantity “1−(R+T)” is equal to the difference between the sum of the transmittance and reflectance (as depicted in FIG. 8A) and unity. Consequently, “1−(R+T)” reflects the amount of light absorbed and/or scattered, and not otherwise reflected or transmitted through the sample. In FIG. 8B, it is apparent that the BaF₂ crack mitigating layer (i.e., Ex. 2C) produces little to no light scattering or absorption as compared to the glass substrate controls (i.e., Ex. 2A). However, when the 8L SCR coating is deposited over the BaF₂ crack mitigating layer (i.e., Exs. 2D and 2E), some scattering and/or absorption occurs, but the levels are generally less than 10% in the 450 nm to 800 nm wavelength range.

### Example 3

### The Origin of the Scattering and/or Absorption Shown in FIG. 8B

A set of twelve samples, Exs. 3A1-A3, 3B1-B3, 3C1-C3 and 3D1-D3, was prepared to investigate light scattering due to surface roughness as the origin for the somewhat decreased transmittance levels observed with articles having a porous BaF₂ crack mitigation layer and an 8L SCR (see, e.g., Exs. 2C and 2D in FIG. 8B). Exs. 3A1-A3 correspond to samples having a bare substrate, a substrate with 200 nm BaF₂ layer deposited at 50° C. and a substrate with a 200 nm BaF₂ layer deposited at 200° C. Exs. 3B1-B3 each have the same structure as the respective samples Exs. 3A1-3A3, along with a 400 nm SiNₓ film disposed over the respective bare substrate or the BaF₂ layer/substrate structure. Exs. 3C1-C3 each have the same structure as the respective samples Exs. 3A1-3A3, along with a 2000 nm SiNₓ film disposed over the respective bare substrate or the BaF₂ layer/substrate structure. Exs. 3D1-D3 each have the same structure as the respective samples Exs. 3A1-3A3, along with a 8L SCR film disposed over the respective bare substrate or the BaF₂ layer/substrate structure.

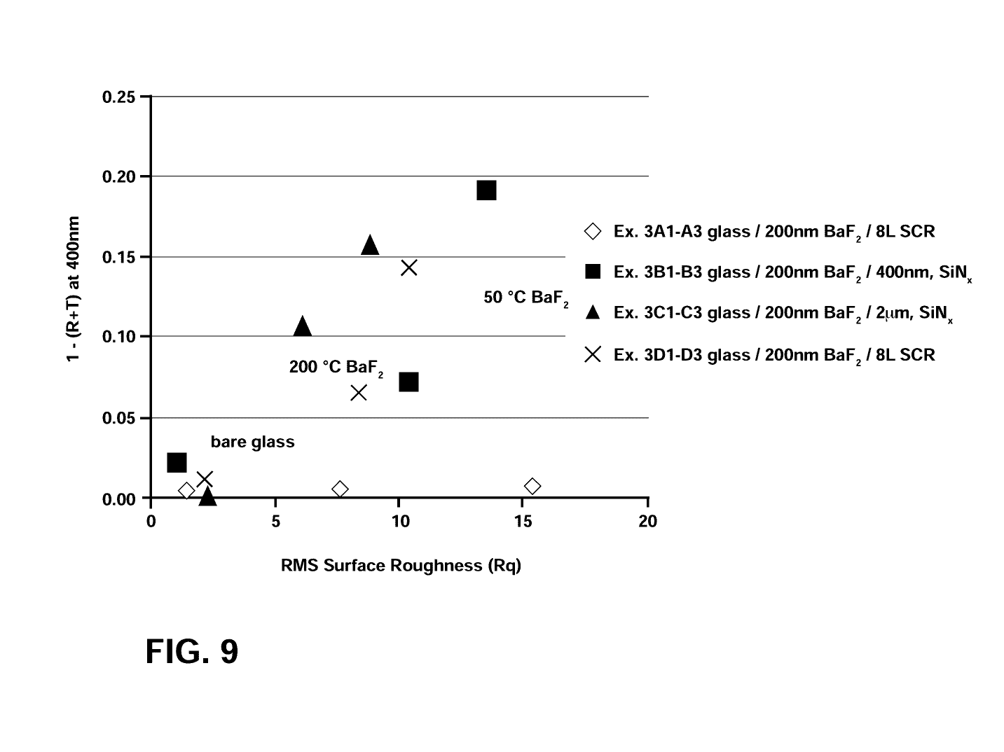

As shown in FIG. 9, transmittance, reflectance and surface roughness measurements were made on the twelve samples designated Exs. 3A1-3D3 to develop a plot of 1−(R+T) at a wavelength of 400 nm vs. root mean squared (“RMS”) surface roughness (R_{q}, nm). The RMS measurements were made on each of the samples using atomic force microscopy (“AFM”) techniques as understood by those with ordinary skill in the field. In FIG. 9, the sample from each of the groups having the most smoothness (i.e., lowest R_{q} values) was the uncoated glass substrates (e.g., Exs. 3A1, 3B1, 3C1 and 3D1). Conversely, the roughest samples were those having a 200 nm BaF₂ layer deposited at 50° C. (e.g., Exs. 3A3, 3B3, 3C3 and 3D3). As such, FIG. 9 shows that the amount of light scattered and/or absorbed by these samples is not impacted by surface roughness for the uncoated glass substrate samples. In contrast, scattering and/or absorption effects are more pronounced and increase with article roughness when the article contains a film of 400 nm SiNₓ, 2000 nm SiNₓ or an 8L SCR stack. Thus, the crack mitigating layer according to this disclosure should possess a surface roughness of <5 nm R_{q} so as to no scatter and/or absorb light and influence the overall optical properties of the article containing such a layer.

### Example 4

### Optical Properties of Laminated Articles Having a BaF₂ Crack Mitigation Layer and a Ten-Layer AR Film

Laminated article samples designated Examples 4A-4D (“Exs. 4A-4D”) were made in Example 4 by providing 1 mm thick ion-exchange strengthened aluminosilicate glass substrates. These substrates possessed the same composition as Example 1. The glass substrates were ion-exchanged in a KNO₃ molten salt bath having a temperature of about 350-450° C. for 3-8 hours. The ion-exchanged glass substrates had a compressive stress of about 687 MPa and an ion-exchange depth of layer of about 24 microns. The glass substrates were then cleaned in a KOH detergent solution (1-4% Semiclean KG), having a temperature of about 50-70° C. with ultrasonic agitation at 40-110 KHz, rinsed in DI water with ultrasonics in the same frequency range, and dried.

In Example 4, the Ex. 4A sample represents a bare glass control. Ex. 4B is also a control as it contains a ten-layer AR (“10L AR”) film having alternating layers of SiO₂ and SiNₓ over the glass substrate (see Table 2 below), but lacks a crack mitigating layer. In the Ex. 4B sample, the 10L AR film was deposited in a Plasma-Therm Versaline HDCVD apparatus at 150° C. In the Ex. 4C sample, a glass substrate and a 10L AR film was prepared according to the Ex. 4B configuration, along with a porous 200 nm thick BaF₂ crack mitigating layer (i.e., as deposited at 50° C.) interposed between the substrate and the 10L AR film. In the Ex. 4D sample, a glass substrate and a 10L AR film was also prepared according to the Ex. 4B configuration, along with a dense 200 nm thick BaF₂ crack mitigating layer (i.e., as deposited at 200° C.) interposed between the substrate and the 10L AR film. The porosity of the porous BaF₂ crack mitigating layer structure (Ex. 4C) was about 19% and the dense BaF₂ crack mitigating layer structure (Ex. 4D) exhibited a porosity of about 4%.

TABLE 2
Ten-layer AR film design for Examples 4A-4D.

| Layer | Examples | Material | Thickness | |
|---|---|---|---|---|
| 1 | 4B, 4C, 4D | SiO₂ | 83.1 | nm |
| 2 | 4B, 4C, 4D | SiNₓ | 82.8 | nm |
| 3 | 4B, 4C, 4D | SiO₂ | 25.2 | nm |
| 4 | 4B, 4C, 4D | SiNₓ | 24.9 | nm |
| 5 | 4B, 4C, 4D | SiO₂ | 73.1 | nm |
| 6 | 4B, 4C, 4D | SiNₓ | 20.6 | nm |
| 7 | 4B, 4C, 4D | SiO₂ | 25.6 | nm |
| 8 | 4B, 4C, 4D | SiNₓ | 116.2 | nm |
| 9 | 4B, 4C, 4D | SiO₂ | 40.1 | nm |
| 10 | 4B, 4C, 4D | SiNₓ | 16.3 | nm |
| Crack | 4C, 4D | BaF₂ | ~200 | nm |
| mitigating layer | | | | |
| Substrate | 4A, 4B, 4C, 4D | Corning ® | ~ 1 | mm |
| | | 5318 Glass | | |

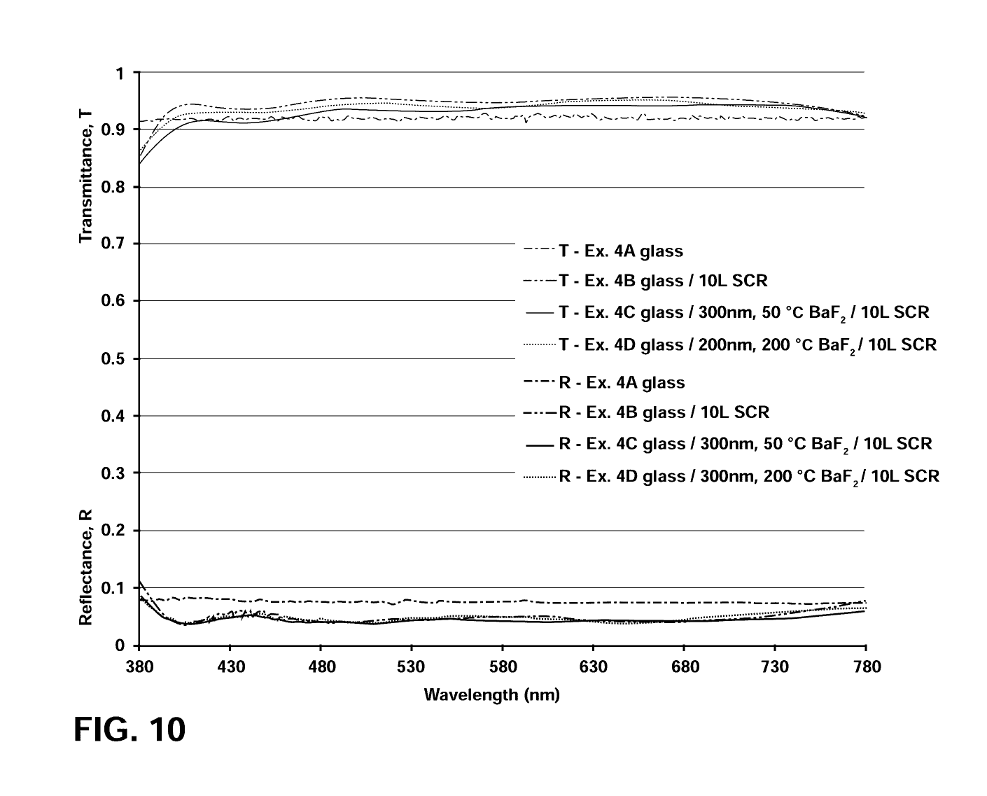

In FIG. 10, reflectance and transmittance spectra are provided for the laminated articles designated Exs. 4A-4D. As such, FIG. 10 presents data that can be used to compare the effects of a porous or dense BaF₂ crack mitigating layer structure on a laminated article having a 10L AR film. The prefix “R” and “T” in the legend each denote series of data that correspond to reflectance and transmittance data, respectively. In FIG. 10, the data presented is indicative of oscillations in the reflectance and transmittance spectra in the optical wavelength regime (i.e., between 380 nm and 700 nm) that are no greater than about 5%. It is evident from comparing the Ex. 4A and Ex. 4B spectra that the addition of the 10L AR film on the substrate does not appreciably increase the magnitude of the reflectance and transmittance oscillations in the optical wavelength regime. Likewise, the presence of the BaF₂ crack mitigating layer in Exs. 4C and 4D between the glass substrate and the 10L AR film also does not appreciably increase the magnitude of the reflectance and transmittance oscillations in the optical wavelength regime. In addition, the presence of the BaF₂ crack mitigating layer in Exs. 4C and 4D also does not appreciably decrease the transmission or increase the reflection from the 10L AR stack. As demonstrated by the data depicted in FIGS. 7-10, BaF₂ crack mitigating layer structures can provide strength retention without compromising the optical properties of the glass substrates and the films (e.g., SiNₓ, 8L SCR and 10L AR films) employed in the laminated articles prepared according to Examples 1-4.

### Example 5

### Strength of Laminated Articles Having Organosilicate Crack Mitigation Layers Derived from Trimethylsilicate (TMS)

In Example 5, sample laminated articles designated Exs. 1A-1B, as described earlier, were also employed in this example. In particular, Exs. 1A and 1B were formed by providing glass substrates having the same composition as Example 1. In addition, a set of laminated articles designated Ex. 1A1 having a bare glass substrate with the same substrate composition as employed in Ex. 1A were processed under similar ion exchange conditions as the samples designated Ex. 1A. All of these glass substrates had a thickness of 1.0 mm. The glass substrates employed in Exs. 1A and 1B were strengthened by ion exchange to provide a surface compressive stress (CS) of about 690 MPa and a compressive depth of layer (DOL) of about 24 μm. The glass substrates employed in Ex. 1A1 were also strengthened by ion exchange to provide a surface CS of about 887 MPa with a DOL of about 42.2 μm. The ion-exchange process for Exs. 1A, 1A1 and 1B was carried out by immersing the glass substrates in a molten potassium nitrate (KNO₃) bath that was heated to a temperature in the range from about 350° C. to 450° C. The glass substrates were immersed in the bath for a duration of 3-8 hours to achieve the surface CS and compressive DOL. After completing the ion exchange process, the glass substrates of Examples 1A, 1A1 and 1B were cleaned in a 2% concentration KOH detergent solution, supplied by Semiclean KG, having a temperature of about 50° C.

In Example 5, the Ex. 1A and Ex. 1A1 samples represent a control as they only contain a glass substrate. Similarly, the Ex. 1B sample also serves as a control because it contains a SiNₓ SCR film having a thickness of about 440 nm and lacks a crack mitigation layer. As noted earlier, the SiNₓ SCR film of Ex. 1B was deposited with a Plasma-Therm Versaline HDPCVD system at 150° C. with silane and nitrogen gases.

Samples designated Ex. 5A, 5B, 5C and 5D were also prepared in Example 5. For the Exs. 5A-5D samples, strengthened glass substrates according to the Ex. 1A1 condition and SiNₓ SCR films according to the Ex. 1B condition were prepared. In addition, Exs. 5A-5D each possess a crack mitigation layer comprising an organosilicate layer derived from trimethylsilicate (TMS) that was disposed between the substrates and the SiNₓ SCR films. Accordingly, the organosilicate layers were disposed over the substrates before the SCR films were deposited on the organosilicate layers. In Exs. 5A and 5B, the TMS layers have a targeted thickness of 50 and ˜300 nm, respectively. These crack mitigation layers were deposited using an atmospheric plasma chemical vapor deposition (APCVD) process in a linear DBD type atmospheric plasma system using 10 sccm TMS and 180 W plasma power in air at room temperature. Similarly, the TMS layers employed in Exs. 5C and 5D have a targeted thickness of 50 and ˜300 nm, respectively. These crack mitigation layers were deposited using an APCVD process in a linear DBD type atmospheric plasma system using 10 sccm TMS and 180 W plasma power in air at 150° C. The actual thicknesses of the respective films employed for Exs. 5A, 5B, 5C and 5D were measured at 52.5 nm, 319.7 nm, 28.1 nm and 315.6 nm, respectively, by techniques employing a stylus profilometer and a scanning electron microscope as understood by those with ordinary skill in the field. Film hardness data for the films in Exs. 5A, 5B, 5C and 5D were measured by nanoindentation, providing values of 0.1, 0.1, 0.44 and 0.44 GPa, respectively. Film modulus data for the films in Exs. 5A, 5B, 5C and 5D were also measured by nanoindentation, providing values of 4, 4, 9 and 9 GPa, respectively.

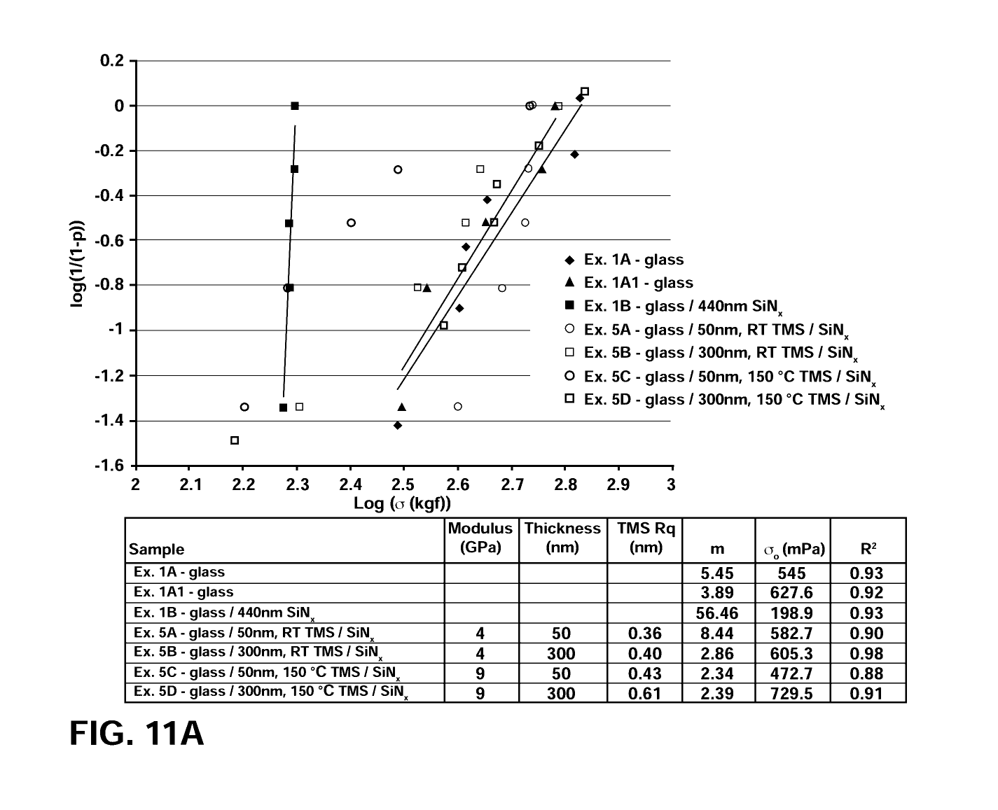

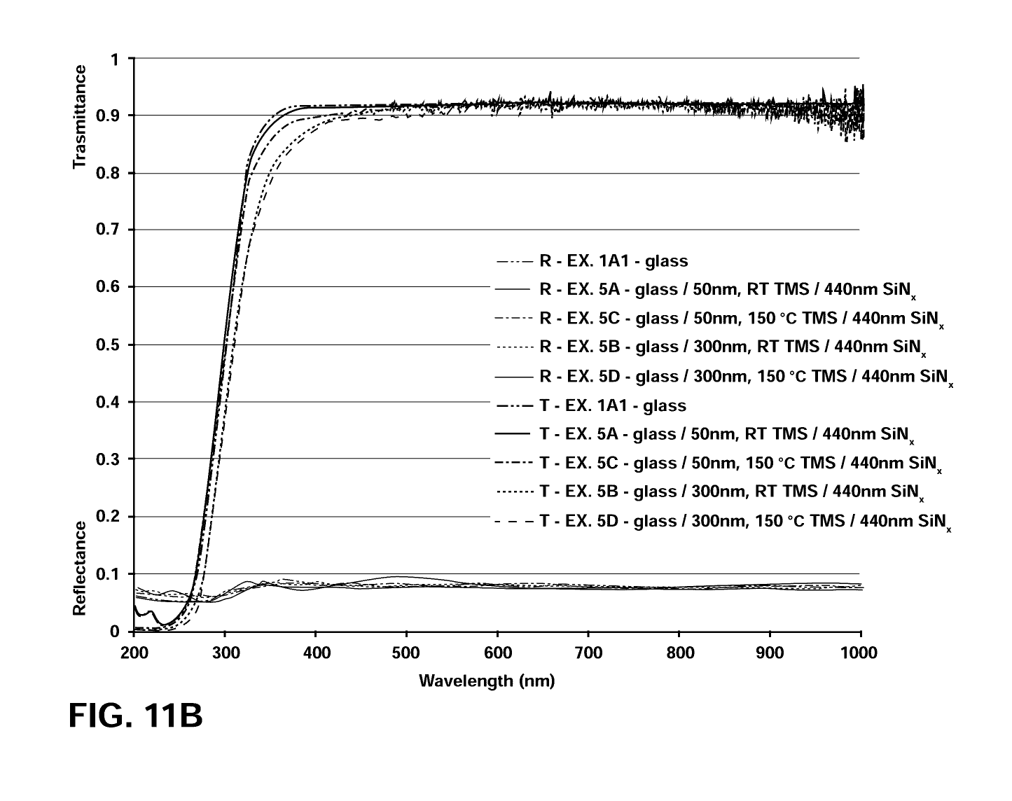

Ring-on-ring (ROR) load to failure testing was used to demonstrate the retention of average flexural strength of Exs. 1A-1B and 5A-5D, as shown in FIG. 11A. For ROR load-to-failure testing, the side with the film and/or crack mitigating layer was placed in tension. The ROR load-to-failure testing parameters included a contact radius of 1.6 mm, a cross-head speed of 1.2 mm/minute, a load ring diameter of 0.5 inches, and a support ring diameter of 1 inch. Before testing, an adhesive film was placed on both sides of the sample being tested to contain broken glass shards.

As illustrated by FIG. 11A, the laminated articles with a crack mitigating layer (Exs. 5A, 5B, 5C and 5D) exhibited greater average flexural strength than the articles comprising strengthened glass substrates with only a SiNₓ SCR film and no crack mitigating layer (Ex. 1B). In particular, the Ex. 1B samples having a SiNₓ SCR film and no crack mitigation layer exhibited a substantial reduction in the average flexural strength compared to the control samples comprising only a strengthened glass substrate with no additional films or layers (Exs. 1A and 1A1).

As also illustrated in FIG. 11A, the addition of a 4 GPa modulus comprising an organosilicate material derived from TMS (Exs. 5A and 5B, respectively) resulted in laminated articles that retained about the same average flexural strength as glass substrates without a crack mitigating layer or film (Exs. 1A and 1A1). Full retention of the glass flexural strength was also observed for Ex. 5D, the laminated article with a 300 nm thick 9 GPa modulus crack mitigating layer. Partial strength retention was observed for Ex. 5C, the laminated article with a thinner 50 nm thick 9 GPa modulus crack mitigating layer. It is believed that the variable flexural strength values observed for Ex. 5C were associated with processing-related issues that led to discontinuities in the crack mitigating layer, resulting in regions of direct or close contact between the substrate and SCR film.

As evidenced by the data presented in FIG. 11A, the crack mitigating layers comprising the organosilicate material derived from TMS likely possess moderate adhesion between the SiNₓ SCR film and/or the glass substrate. Surface energy measurements of the 50 nm and 300 nm organosilicate films prepared according to Example 5 were performed. In particular, the 50 and 300 nm organosilicate films exhibited total surface energy levels of 29.07 and 28.72 mJ/m², respectively. These surface energy levels are below the surface energy values associated with typical hydrocarbon polymers in the literature, and would be expected to result in moderate adhesion between the substrate and the SiNₓ films employed in the laminated articles in this example. Moreover, the relatively low elastic modulus of the crack mitigating layers employed in Exs. 5A, 5B, 5C and 5D also plays a role in the strength retention observed in FIG. 11A. As outlined earlier in the disclosure, the elastic modulus values of these films, 4 GPa and 9 GPa, is sufficiently low to facilitate crack deflection between the SCR film and the underlying structure, ensuring that the presence of the SCR film does not negatively influence the overall strength of the article.

### Example 5A

### Optical Properties of Laminated Articles Having an Organosilicate Crack Mitigation Layer and a SiNₓ Scratch-Resistant Film

The laminated article samples Ex. 1A1 and Exs. 5A-5D were employed in Example 5A to assess the optical properties of laminated articles containing organosilicate crack mitigation layers beneath SiNₓ SCR films. In FIG. 11B, reflectance and transmittance spectra are provided for the laminated articles designated Exs. 1A1, 5A-5D. The prefix “R” and “T” in the legend each denote series of data that correspond to reflectance and transmittance data, respectively. The transmission levels for the articles containing the organosilicate crack mitigation layers derived from TMS (Exs. 5A-5D) are nearly identical to that of the bare glass substrates (Ex. 1A1) except for a small reduction in transmission at wavelengths below 450 nm. The average reduction in transmission for the articles containing the organosilicate layers, Exs. 5A-5D, relative to the bare glass substrates, Ex. 1A1, over the visible wavelength range (380 to 830 nm) is 0.9%, 1.1%, 0.7%, 1.3%, respectively. Further, the average reduction in transmission for these same samples is 1.2%, 3.5%, 1.2%, and 4.9%, respectively, relative to the samples, Ex. 1A1, containing a bare glass substrate.

### Example 6

### Optical Properties of Laminated Articles Having an Organosilicate Crack Mitigation Layer and a Nine-Layer AR Film

In Example 6, laminated article samples were made by providing 1 mm thick ion-exchange strengthened aluminosilicate glass substrates, consistent with the bare glass substrate control designated Ex. 4A and the glass substrate/10L DAR film control designated Ex. 4B (see Example 4). These substrates possessed the same composition as Example 1. The glass substrates were ion-exchanged in a KNO₃ molten salt bath having a temperature of about 350-450° C. for 3-8 hours. The ion-exchanged glass substrates had a compressive stress of about 687 MPa and an ion-exchange depth of layer of about 24 microns. The glass substrates were then cleaned in a KOH detergent solution (1-4% Semiclean KG), having a temperature of about 50-70° C. with ultrasonic agitation at 40-110 KHz, rinsed in DI water with ultrasonics in the same frequency range, and dried. The Ex. 4A sample represents a control as it only contains a glass substrate. Similarly, the Ex. 4B sample also serves as a control because it contains a ten-layer durable antireflective (10L DAR) film. In particular, the 10L DAR film employed in Ex. 4B comprises alternating layers of SiO₂ and SiNₓ over the glass substrate (see Table 2 above), but lacks a crack mitigating layer. In the Ex. 4B sample, the 10L DAR film was deposited with a Plasma-Therm HDPCVD apparatus.

With regard to the Exs. 6A and 6A samples also employed in Example 6, these articles also contain a 10L DAR film, processed similarly as the laminated articles designated by Ex. 4B. In addition, the Exs. 6A and 6A samples possess a crack mitigation layer comprising an organosilicate layer derived from TMS having a thickness of about 50 nm and 300 nm, respectively, beneath the 10L DAR film. In particular, the organosilicate material derived from TMS used in Exs. 6A and 6A was processed under the same conditions as Employed for the Exs. 5A and 5B samples, respectively (i.e., deposition at room temperature, targeting 50 nm and 300 nm thicknesses), as described in connection with Example 5.

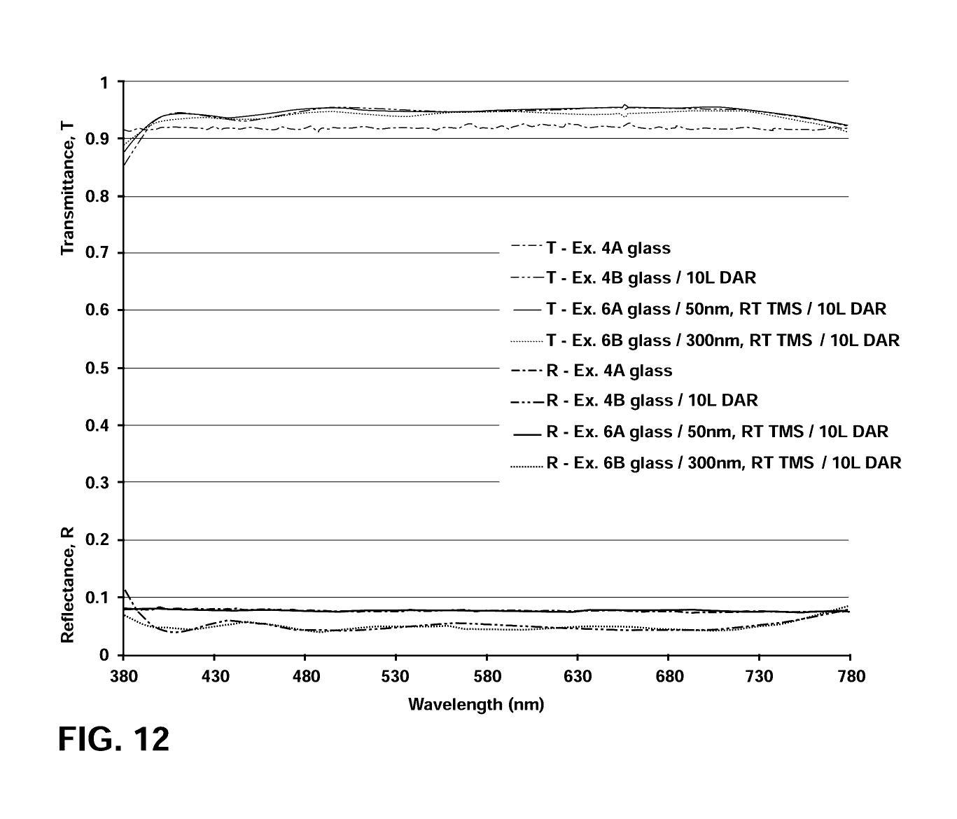

In FIG. 12, reflectance and transmittance spectra are provided for the laminated articles designated Exs. 4A, 4B, 6A and 6B. The prefix “R” and “T” in the legend each denote series of data that correspond to reflectance and transmittance data, respectively. More specifically, the transmittance spectra in the optical wavelength regime (i.e., between about 400 nm and 780 nm) for each of the samples designated Exs. 4A, 4B, 6A and 6B is 92.1%, 94.8%, 94.7%, and 94.3%, respectively. Inclusion of the organosilicate crack mitigating layer in the Exs. 6A and 6B samples relative to the control containing the 10L DAR film, Ex. 4B, resulted in a decrease in the overall transmittance of no greater than 0.5%. Put another way, the organosilicate layer had little influence in the overall transmittance of the article.

### Example 7

### Strength of Laminated Articles Having Organosilicon Crack Mitigation Layers

Sample laminated articles designated Examples 7A-7F (“Exs. 7A-7F”) were formed by providing glass substrates having the same composition as Example 1. The glass substrates had a thickness of 1.0 mm. The glass substrates were strengthened by ion exchange to provide a surface compressive stress (CS) of about 687 MPa and a compressive depth of layer (DOL) of about 24 μm. The ion-exchange process was carried out by immersing the glass substrate in a molten potassium nitrate (KNO₃) bath that was heated to a temperature in the range from about 350° C. to 450° C. The glass substrates were immersed in the bath for a duration of 3-8 hours to achieve the surface CS and compressive DOL. After completing the ion exchange process, the glass substrates of Examples 7A-7F were cleaned in a 2% concentration KOH detergent solution, supplied by Semiclean KG, having a temperature of about 50° C.

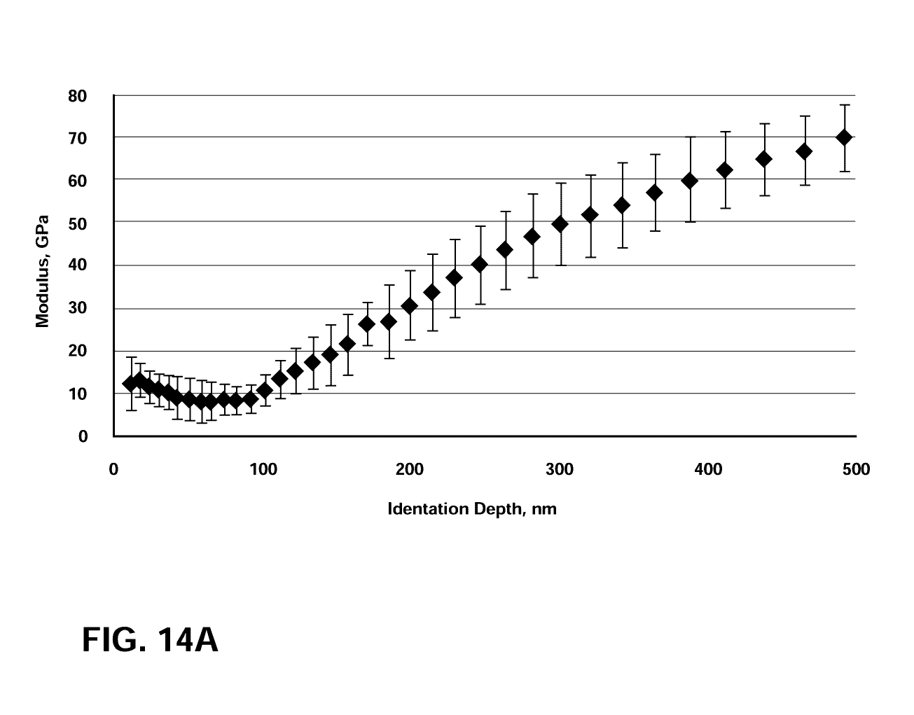

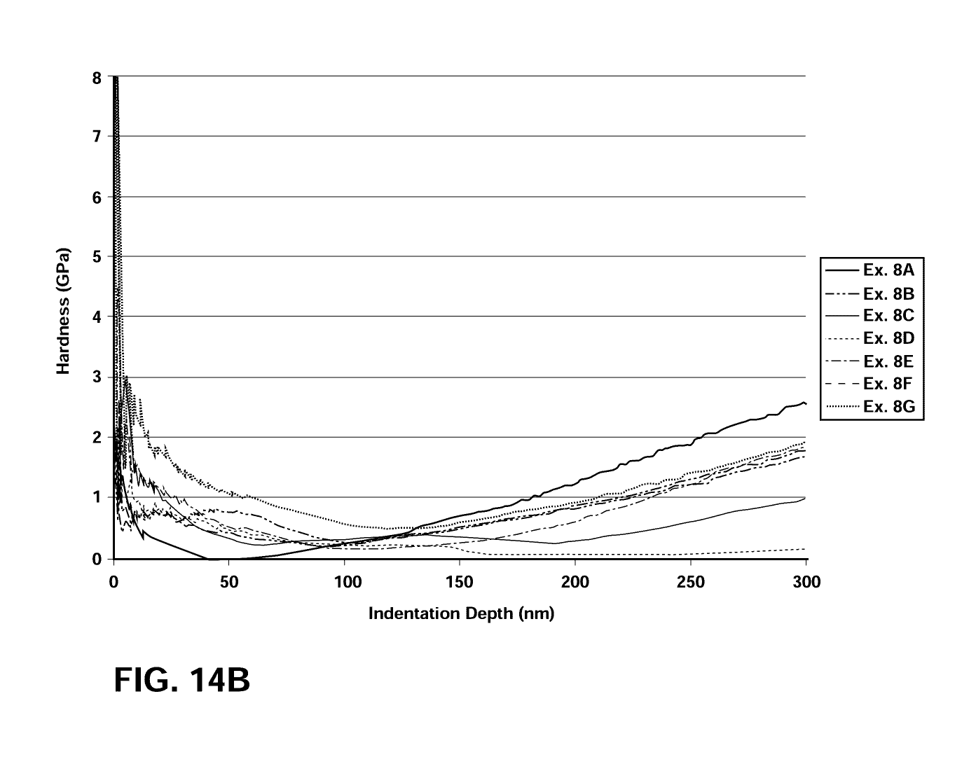

In Example 7, the Ex. 7A sample represents a control as it only contains a glass substrate. Similarly, the Exs. 7D1 and 7D2 samples also serve as a control because they contain an ITO transparent conductive film having a thickness of about 100 nm and lack a crack mitigation layer. In the Ex. 7D1 and 7D2 samples, the ITO film was deposited. In the Ex. 7B, 7C, 7E and 7F samples, glass substrates and ITO films were employed according to the Exs. 7A, 7D1, and 7D2. In addition, Exs. 7B, 7C, 7E and 7F each possess a crack mitigation layer comprising an organosilicon film deposited using an AP plasma-enhanced CVD process with an HMDSO precursor. The organosilicon films of Exs. 7B, 7C, 7E and 7F have a thickness of 10, 25, 50 and 100 nm, respectively. In addition, the organosilicon films employed in the glass substrates of Exs. 7B, 7C, 7E and 7F have an elastic modulus of about 12 GPa and a hardness of less than 2 GPa (see FIGS. 14A and 14B).

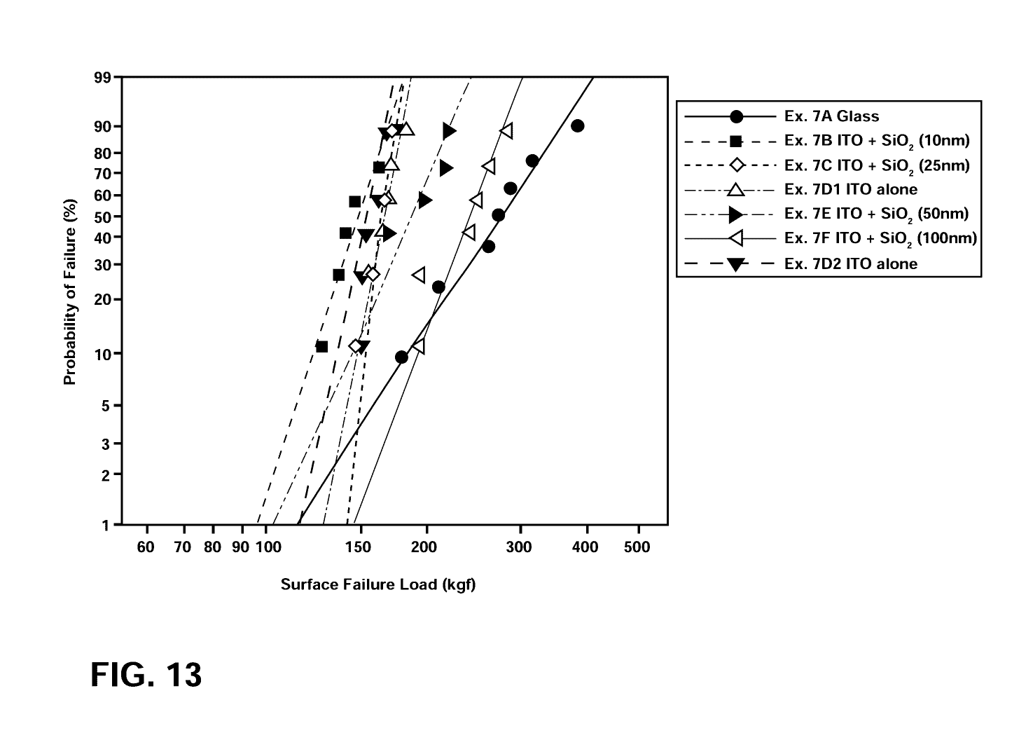

ROR load to failure testing was used to demonstrate the retention of average flexural strength of Exs. 7A-7F, as shown in FIG. 13. For ROR load-to-failure testing, the side with the film and/or crack mitigating layer was placed in tension. The ROR load-to-failure testing parameters included a contact radius of 1.6 mm, a cross-head speed of 1.2 mm/minute, a load ring diameter of 0.5 inches, and a support ring diameter of 1 inch. Before testing, an adhesive film was placed on both sides of the sample being tested to contain broken glass shards.

As illustrated in FIG. 13, the addition of a crack mitigating layer comprising an organosilicon having a thickness of 50 nm or 100 nm (Exs. 7E and 7F, respectively) resulted in laminated articles that retained almost the same average flexural strength as glass substrates without a crack mitigating layer or film (Ex. 7A). For example, the glass substrates having the 50 nm organosilicon crack mitigating layer (Ex. 7E) retained about 66% of the strength of the “bare” substrates having no crack mitigating layer or ITO film (Ex. 7A). The glass substrates having the 100 nm organosilicon crack mitigating layer (Ex. 7F) retained about 84% of the strength of the “bare” substrates having no crack mitigating layer or ITO film (Ex. 7A). Moreover, the articles with a crack mitigating layer (Exs. 7E and 7F) exhibited greater average flexural strength than the articles comprising strengthened glass substrates with only an ITO film and no crack mitigating layer (Exs. 7D1 and 7D2). In particular, the Exs. 7D1 and 7D2 samples having an ITO film and no crack mitigation layer exhibited a substantial reduction in the average flexural strength compared to the control samples comprising only a strengthened glass substrate with no additional films or layers (Ex. 7A).

Referring to FIG. 14A, a graph plots elastic modulus data as a function of indentation depth for an organosilicon crack mitigating layer prepared using an atmospheric pressure plasma-enhanced CVD process employing a HDMSO precursor according to an aspect of the disclosure. The organosilicon film employed as the source for the data presented in FIG. 14A is comparable to the organosilicon films employed in Exs. 7B, 7D, 7E and 7F. Notably, the data in FIG. 14A demonstrates that the organosilicon layer has an elastic modulus of about 12 GPa for an indentation depth of up to 100 nm. It is believed that the elastic modulus data for indentation depths that exceed 100 nm is influenced by testing-related artifacts.

Referring to FIG. 14B, a graph plots hardness data as a function of indentation depth for the organosilicon crack mitigating layer samples used to generate the data in FIG. 14A. For FIG. 14B, the data series identified by “Exs. 8A-8G” correspond to individual hardness test runs for substrates having the same organosilicon layer. As demonstrated by FIG. 14B, the organosilicon layer has a hardness of less than 2 GPa. Here, the is believed that the hardness data associated the first few nanometers of depth and indentation depths that exceed 100 nm is influenced by testing-related artifacts.

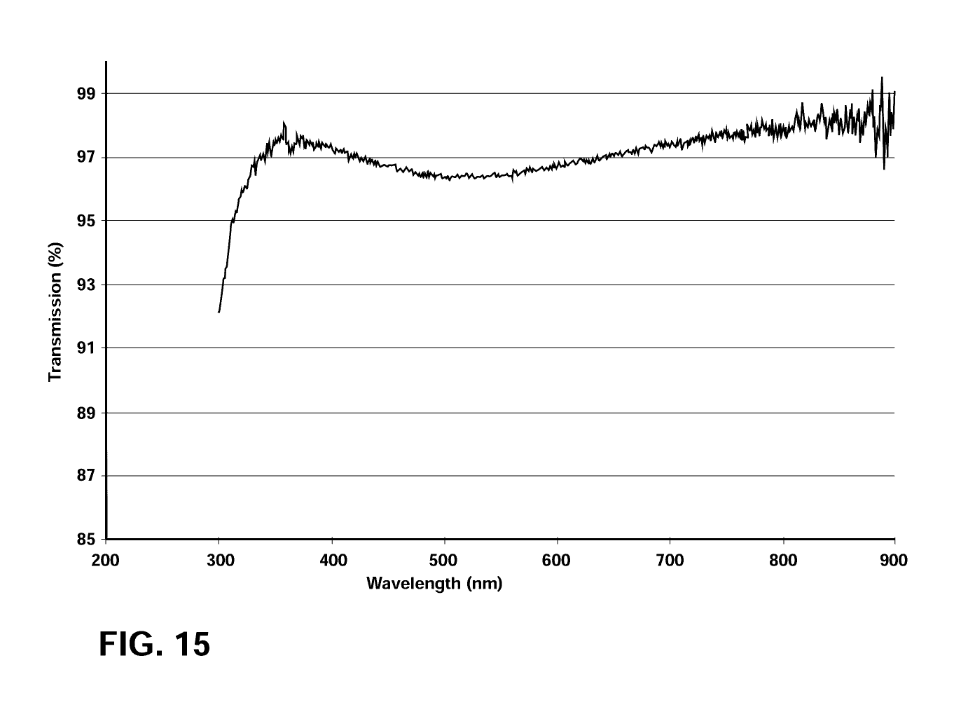

Referring to FIG. 15, a graph is provided that presents optical transmittance data for an organosilicon crack mitigating layer having a thickness of about 100 nm. The layer was prepared using an atmospheric pressure plasma-enhanced CVD process. As FIG. 15 demonstrates, a 100 nm organosilicon layer exhibits an optical transmittance of above 90% over a broad wavelength range from 300 to about 900 nm that includes visible wavelengths.

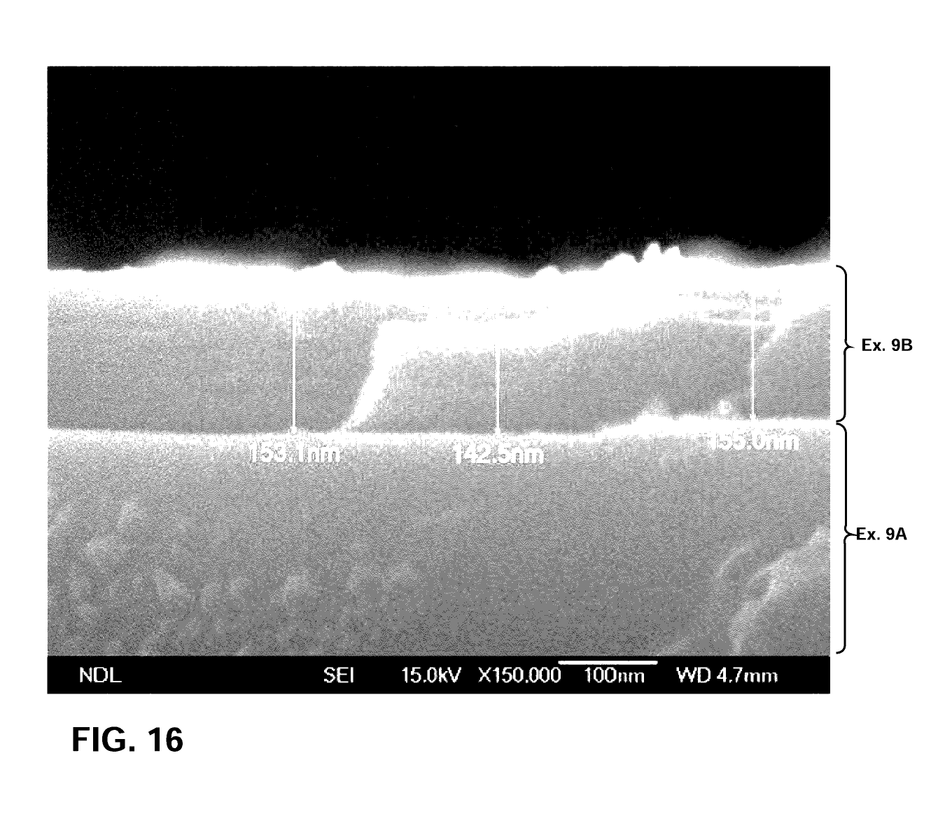

In FIG. 16, a scanning electron microscope (SEM) image from a cross section of a glass substrate with an organosilicon crack mitigating layer having a thickness of about 150 nm is provided. The layer was prepared using an atmospheric pressure plasma-enhanced CVD process according to a further aspect of this disclosure. As FIG. 16 indicates, the organosilicon layer has a fairly constant thickness from about 143 to about 155 nm in the selected region.

While the disclosure has been described with respect to a limited number of embodiments for the purpose of illustration, those skilled in the art, having benefit of this disclosure, will appreciate that other embodiments can be devised which do not depart from the scope of the disclosure as disclosed herein. Accordingly, various modifications, adaptations and alternatives may occur to one skilled in the art without departing from the spirit and scope of the present disclosure.

We claim:

1. An article, comprising:
a glass substrate having opposing major surfaces;
a crack mitigating layer disposed on a first major surface; and
a film disposed on the crack mitigating layer,
wherein the crack mitigating layer is characterized by an elastic modulus of about 20 GPa or less, and
further wherein the refractive index of the crack mitigating layer is greater than or equal to the refractive index of the substrate and less than or equal to the refractive index of the film.

2. The article of claim 1, wherein the crack mitigating layer further comprises an organosilicate material.

3. The article of claim 1, wherein the crack mitigating layer has a thickness of about 300 nm or less.

4. The article of claim 1, wherein the film comprises silicon nitride, silicon oxynitride, aluminum oxynitride, aluminum nitride, silicon aluminum oxynitride or indium tin oxide.

5. The article of claim 1, wherein the film is an antireflective film comprising a multilayer structure having alternating layers of a first material and a second material, wherein the first material comprises silicon nitride, silicon oxynitride, aluminum oxynitride, aluminum nitride, silicon aluminum oxynitride or indium tin oxide and the second material comprises silicon oxide or silicon oxynitride.

6. The article of claim 1, wherein the crack mitigating layer comprises a metal fluoride layer having a porosity of 20% or less.

7. The article of claim 2, wherein the organosilicate material is a methylated silica material, wherein the methylated silica is deposited with a chemical vapor deposition (CVD) process and derived from a trimethylsilane precursor.

8. The article of claim 2, wherein the organosilicate material is deposited with a plasma-enhanced chemical vapor deposition (PECVD) process and derived from a hexyamethyldisiloxane (HMDSO) precursor.

9. An article, comprising:
a glass substrate having opposing major surfaces;
a crack mitigating layer disposed on a first major surface forming a first interface; and
a film disposed on the crack mitigating layer forming a second interface,
wherein the article exhibits an effective adhesion energy at one or more of the first interface and the second interface of less than about 4 J/m², and
further wherein the refractive index of the crack mitigating layer is greater than or equal to the refractive index of the substrate and less than or equal to the refractive index of the film.

10. The article of claim 9, wherein the crack mitigating layer further comprises an organosilicate material.

11. The article of claim 9, wherein the crack mitigating layer has a thickness of about 300 nm or less.

12. The article of claim 9, wherein the film comprises silicon nitride.

13. The article of claim 9, wherein the crack mitigating layer comprises a metal fluoride layer having a porosity of 20% or less.

14. The article of claim 10, wherein the organosilicate material is a methylated silica material.

15. An article, comprising:
a glass substrate having opposing major surfaces; and
a crack mitigating layer disposed on a first major surface forming a first interface, the first interface having an effective adhesion energy of less than about 4 J/m², and
wherein the refractive index of the crack mitigating layer is greater than or equal to the refractive index of the substrate, and
further wherein the substrate and crack mitigating layer each comprise an optical transmittance and the optical transmittance of the crack mitigating layer varies by 1% or less from the optical transmittance of the substrate.

16. The article of claim 15, wherein the crack mitigating layer comprises a metal fluoride layer having a porosity of 20% or less.

17. The article of claim 15, wherein the crack mitigating layer further comprises an organosilicate material.

18. The article of claim 17, wherein the organosilicate material is a methylated silica material deposited with a chemical vapor deposition (CVD) process and derived from a trimethylsilane precursor.

19. The article of claim 17, wherein the organosilicate material is deposited with a plasma-enhanced chemical vapor deposition (PECVD) process and derived from a hexyamethyldisiloxane (HMDSO) precursor.

20. The article of claim 19, wherein the crack mitigating layer has a thickness from about 50 nm to about 150 nm.

21. A device comprising:
a housing having front, back, and side surfaces;
electrical components that are at least partially inside the housing; and
a display at or adjacent to the front surface of the housing;
wherein the article of claim 1 is disposed over the display.

22. A device comprising:
a housing having front, back, and side surfaces;
electrical components that are at least partially inside the housing; and
a display at or adjacent to the front surface of the housing;
wherein the article of claim 9 is disposed over the display.

23. A device comprising:
a housing having front, back, and side surfaces;
electrical components that are at least partially inside the housing; and
a display at or adjacent to the front surface of the housing;
wherein the article of claim 15 is disposed over the display.
